(19) United States
(12) Patent Application Publication
(10) Pub. No.: US 2026/0282493 A1
(43) Pub. Date: Sep. 17, 2026

(54) SELF-ALIGNED SIDEWALL CONTACT FOR BACKSIDE INTERCONNECT

(71) Applicant: INTERNATIONAL BUSINESS MACHINES CORPORATION, ARMONK, NY (US)

(72) Inventors: Eunsoo Cho, Albany, NY (US); Ruilong Xie, Niskayuna, NY (US); Shay Reboh, Guilderland, NY (US); Shahrukh Khan, Sandy Hook, CT (US); Tenko Yamashita, Schenectady, NY (US)

(21) Appl. No.: 19/079,534

(22) Filed: Mar. 14, 2025

(51) Int. Cl. H10D 64/23; H10D 30/00; H10D 30/01; H10D 30/43; H10D 62/10; H10D 84/01; H10D 84/83

(52) U.S. Cl. CPC H10D 64/259; H10D 30/014; H10D 30/0191; H10D 30/43; H10D 30/502; H10D 62/121; H10D 84/0149; H10D 84/832

(57) ABSTRACT

A microelectronic structure that includes a stacked FET including a frontside transistor and a backside transistor, wherein an active region of the frontside transistor and an active region of the backside transistor are offset from each other. A frontside contact that includes a horizontal section and a frontside via section, wherein the horizontal section is in contact with a frontside surface of a frontside source/drain and the frontside via section is in direct contact with a vertical side surface of the frontside source/drain, wherein the frontside via section extends towards the backside region of the stacked FET.

### BACKGROUND

The present invention generally relates to the field of microelectronics, and more particularly to backside contact formation in a shifted stacked FET.

Establishing the connection between the two or more metal layers within a microelectronic structure often includes various processes, such as, but not limited to removal/etching and/or patterning/lithography. In a stacked FET design, establishing these connections may be further complicated by the alignments of the active regions of the upper and lower transistors.

### BRIEF SUMMARY

Additional aspects and/or advantages will be set forth in part in the description which follows and, in part, will be apparent from the description, or may be learned by practice of the invention.

A microelectronic structure that includes a stacked FET including a stacked FET including a frontside section of the stacked FET and a backside section of stacked FET, wherein an active region of the frontside section of the stacked FET and an active region of the backside section of stacked FET are offset from each other. A frontside contact that includes a horizontal section and a frontside via section, wherein the horizontal section is in contact with a frontside surface of a frontside source/drain and the frontside via section is in direct contact with a vertical side surface of the frontside source/drain, wherein the frontside via section extends towards the backside region of the stacked FET.

A microelectronic structure that includes a stack FET array, wherein the stacked FET array includes at least a first stacked FET and a second stacked FET, wherein the first stack FET is located adjacent to the second stack FET, wherein the first stacked FET includes a first frontside section and a first backside section. A first frontside contact that includes a horizontal section and a frontside via section, wherein the horizontal section is in contact with a frontside surface of a first frontside source/drain and the frontside via section is in direct contact with a first vertical side surface of the first frontside source/drain, wherein the frontside via section extends towards a backside region of the first stacked FET.

A method comprising forming a stack FET array, wherein the stacked FET array includes at least a first stacked FET and a second stacked FET, wherein the first stack FET is located adjacent to the second stack FET, wherein the first stacked FET includes a first frontside section and a first backside section. Forming a first frontside contact that includes a horizontal section and a frontside via section, wherein the horizontal section is in contact with a frontside surface of a first frontside source/drain and the frontside via section is in direct contact with a first vertical side surface of the first frontside source/drain, wherein the frontside via section extends towards a backside region of the first stacked FET.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of the microelectronic structure, in accordance with the embodiment of the present invention.

FIG. 2A illustrates a cross-section X of the microelectronic structure prior to initial processing including a first substrate layer, an etch stop layer, a second substrate layer, a first lower source/drain, a second lower source/drain, lower gate material, lower inner spacers, and lower channel layers, in accordance with the embodiment of the present invention.

FIG. 2B illustrates a cross-section Y1 of the microelectronic structure prior to initial processing including a first substrate layer, an etch stop layer, a second substrate layer, a shallow trench isolation (STI) layer, lower gate material, lower channel layers, and a lower gate cut, in accordance with the embodiment of the present invention.

FIG. 2C illustrates a cross-section Y2 of the microelectronic structure prior to initial processing including a first substrate layer, an etch stop layer, a second substrate layer, a shallow trench isolation (STI) layer, a first lower source/drain, a second lower source/drain, lower channel layers, a via, and a via dielectric liner, in accordance with the embodiment of the present invention.

FIG. 3A illustrates the cross-section X of the microelectronic structure after formation of a middle dielectric isolation layer and bonding of a top channel, in accordance with the embodiment of the present invention.

FIG. 3B illustrates the cross-section Y1 of the microelectronic structure after formation of a middle dielectric isolation layer and bonding of a top channel, in accordance with the embodiment of the present invention.

FIG. 3C illustrates the cross-section Y2 of the microelectronic structure after formation of a middle dielectric isolation layer and bonding of a top channel, in accordance with the embodiment of the present invention.

FIG. 4A illustrates a cross-section X of the microelectronic structure after patterning of the upper channel layers and upper gate placeholder layers and formation of the upper inner spacers, a dummy gate, an upper dielectric isolation layer, a first upper source/drain, and a second upper source/drain, in accordance with the embodiment of the present invention.

FIG. 4B illustrates a cross-section Y1 of the microelectronic structure after patterning of the upper channel layers and upper gate placeholder layers and formation of the dummy gate, in accordance with the embodiment of the present invention.

FIG. 4C illustrates a cross-section Y2 of the microelectronic structure after the formation of the first upper source/drain, the second upper source/drain, the upper source/drain spacers, and the upper dielectric isolation layer, in accordance with the embodiment of the present invention.

FIG. 5A illustrates a cross-section X of the microelectronic structure after removal of the dummy gate and formation of the upper gate, in accordance with the embodiment of the present invention.

FIG. 5B illustrates a cross-section Y1 of the microelectronic structure after removal of the dummy gate and formation of the upper gate, gate openings, and upper gate cut, in accordance with the embodiment of the present invention.

FIG. 5C illustrates a cross-section Y2 of the microelectronic structure after removal of the dummy gate, in accordance with the embodiment of the present invention.

FIG. 6A illustrates a cross-section X of the microelectronic structure after removal of a portion of the upper gate and upper inner spacers, in accordance with the embodiment of the present invention.

FIG. 6B illustrates a cross-section Y1 of the microelectronic structure after removal of a portion of the upper gate and upper gate cut, in accordance with the embodiment of the present invention.

FIG. 6C illustrates a cross-section Y2 of the microelectronic structure after removal of a portion of the upper gate, in accordance with the embodiment of the present invention.

FIG. 7A illustrates a cross-section X of the microelectronic structure after formation of a self-aligned contact (SAC) cap, in accordance with the embodiment of the present invention.

FIG. 7B illustrates a cross-section Y1 of the microelectronic structure after formation of a self-aligned contact (SAC) cap, in accordance with the embodiment of the present invention.

FIG. 7C illustrates a cross-section Y2 of the microelectronic structure after formation of a self-aligned contact (SAC) cap, in accordance with the embodiment of the present invention.

FIG. 8A illustrates a cross-section X of the microelectronic structure after the formation of a lithography layer and SiARC layer and removal of portions of the lithography layer and the SiARC layer, in accordance with the embodiment of the present invention.

FIG. 8B illustrates a cross-section Y1 of the microelectronic structure after the formation of a lithography layer and SiARC layer, in accordance with the embodiment of the present invention.

FIG. 8C illustrates a cross-section Y2 of the microelectronic structure after the formation of a lithography layer and SiARC layer and removal of portions of the lithography layer and the SiARC layer, in accordance with the embodiment of the present invention.

FIG. 9A illustrates a cross-section X of the microelectronic structure after the removal of SiARC layer, a portion of the self-aligned contact (SAC) CAP, and a portion of the second upper source/drain, in accordance with the embodiment of the present invention.

FIG. 9B illustrates a cross-section Y1 of the microelectronic structure after removal of the SiARC layer, in accordance with the embodiment of the present invention.

FIG. 9C illustrates a cross-section Y2 of the microelectronic structure after removal of the SiARC layer and removal of a portion of the upper dielectric isolation layer, in accordance with the embodiment of the present invention.

FIG. 10A illustrates a cross-section X of the microelectronic structure after selective dielectric reactive ion etching (RIE), in accordance with the embodiment of the present invention.

FIG. 10B illustrates a cross-section Y1 of the microelectronic structure after selective dielectric reactive ion etching (RIE), in accordance with the embodiment of the present invention.

FIG. 10C illustrates a cross-section Y2 of the microelectronic structure after selective dielectric reactive ion etching (RIE), in accordance with the embodiment of the present invention.

FIG. 11A illustrates a cross-section X of the microelectronic structure after formation of the upper source/drain contacts, in accordance with the embodiment of the present invention.

FIG. 11B illustrates a cross-section Y1 of the microelectronic structure after formation of the upper gate contacts, in accordance with the embodiment of the present invention.

FIG. 11C illustrates a cross-section Y2 of the microelectronic structure after formation of the upper source/drain contacts and the first lower source/drain contact, in accordance with the embodiment of the present invention.

FIG. 12A illustrates a cross-section X of the microelectronic structure after formation of the upper dielectric isolation layer extension, a plurality of metal line(s) or metal track(s), the back end of the line layer (BEOL), and the carrier wafer, in accordance with the embodiment of the present invention.

FIG. 12B illustrates a cross-section Y1 of the microelectronic structure after formation of the upper dielectric isolation layer extension, a plurality of metal line(s) or metal track(s), the back end of the line layer (BEOL), and the carrier wafer, in accordance with the embodiment of the present invention.

FIG. 12C illustrates a cross-section Y2 of the microelectronic structure after formation of the upper dielectric isolation layer extension, a plurality of metal line(s) or metal track(s), the back end of the line layer (BEOL), and the carrier wafer, in accordance with the embodiment of the present invention.

FIG. 13A illustrates a cross-section X of the microelectronic structure after flipping of the device over for backside processing and after first substrate layer removal, in accordance with the embodiment of the present invention.

FIG. 13B illustrates a cross-section Y1 of the microelectronic structure after flipping of the device over for backside processing and after first substrate layer removal, in accordance with the embodiment of the present invention.

FIG. 13C illustrates a cross-section Y2 of the microelectronic structure after flipping of the device over for backside processing and after first substrate layer removal, in accordance with the embodiment of the present invention.

FIG. 14A illustrates a cross-section X of the microelectronic structure after removal of the etch stop layer and the second substrate layer, in accordance with the embodiment of the present invention.

FIG. 14B illustrates a cross-section Y1 of the microelectronic structure after removal of the etch stop layer and the second substrate layer, in accordance with the embodiment of the present invention.

FIG. 14C illustrates a cross-section Y2 of the microelectronic structure after removal of the etch stop layer and the second substrate layer, in accordance with the embodiment of the present invention.

FIG. 15A illustrates a cross-section X of the microelectronic structure after formation of the backside interlayer dielectric layer (BILD), in accordance with the embodiment of the present invention.

FIG. 15B illustrates a cross-section Y1 of the microelectronic structure after formation of the backside interlayer dielectric layer (BILD), in accordance with the embodiment of the present invention.

FIG. 15C illustrates a cross-section Y2 of the microelectronic structure after formation of the backside interlayer dielectric layer (BILD), in accordance with the embodiment of the present invention.

FIG. 16A illustrates a cross-section X of the microelectronic structure after backside contact and backside interconnect formation, in accordance with the embodiment of the present invention.

FIG. 16B illustrates a cross-section Y1 of the microelectronic structure after backside contact and backside interconnect formation, in accordance with the embodiment of the present invention.

FIG. 16C illustrates a cross-section Y2 of the microelectronic structure after backside contact and backside interconnect formation, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. A stack FET cell includes one upper transistor and one lower transistor with opposite polarity (e.g., one is an NFET, and the other is PFET). The present invention is directed towards a stacked FET in which the top/upper active region is shifted/offset with respect to the lower/bottom active region. In stacked FETs in which the top/upper active region is shifted/offset with respect to the lower/bottom active region it may be challenging to form enough contact area and low Rhoc (rho) for the backside contacts. Additionally, existing approaches to the shifted FETs impose limitations on backside contact formation and/or area scaling. As will be described in detail below, the invention replaces a spacer on at least one side of the upper source/drain with a sidewall contact wiring the top source/drain to a via at the lower/bottom transistor layer which in combination with other features of the invention overcomes the limitations of the current state of the art.

The present invention is directed towards a stacked FET in which the lower/bottom transistor is the PFET, and the upper/top transistor is the NFET. The top/upper active region being shifted with respect to the lower/bottom active region. This invention enables an improvement to contact formation in shifted stacked FETs by confining the top source/drains with spacers, the spacers being the same material as the gate spacers (e.g., inner spacers). One of the spacers confining the top source/drain epis can then be removed and replaced by a sidewall contact that wires the top source/drain to the via at the lower/bottom transistor layer. The via may have a via dielectric liner that may separate the via metal from the lower source/drains. In preferred embodiments of the present invention, the first lower source/drain (e.g., first backside source/drain, first PFET source/drain) and the second lower source/drain (e.g., second backside source/drain, second PFET source/drain) may both be PFET and the first upper source/drain (e.g., first frontside source/drain, first NFET source/drain) and the second upper source/drain (e.g., second frontside source/drain, second NFET source/drain) may both be NFET. This configuration of the lower source/drains both being PFET and the lower source/drains extending deeper than the date into the second substrate enables a more effective backside contact formation which is critical for the contact resistance aspects of the FET performance. The present invention enables easier backside contact formation for the upper source/drains as compared to deep direct backside contact (DBC) approaches and facilitates area scaling when compared to conventional two-stage via approaches.

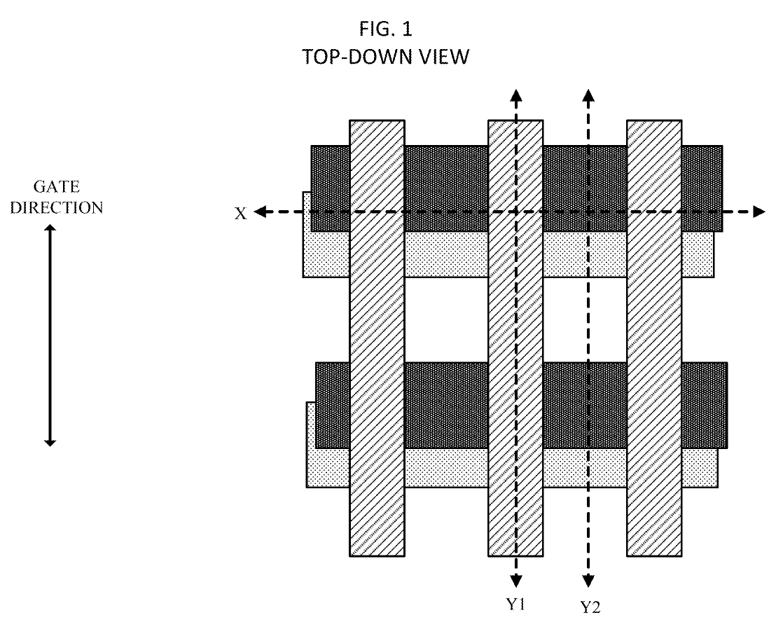

FIG. 1 illustrates a top-down view of multiple devices, in accordance with the embodiment of the present invention. The cross-section X extends horizontally through nanosheet transistors. Cross-section Y1 and cross-section Y2 are perpendicular to cross-section X. Cross-section X is perpendicular to the gate direction and cross-sections Y1 and Y2 are parallel to the gate direction. Cross-sections Y1 and Y2 extend through a source/drain region that spans across multiple adjacent transistors, at least one transistor stacking over another transistor with the top active region shifted with respect to the bottom active region. Cross-section Y1 extending through a gate.

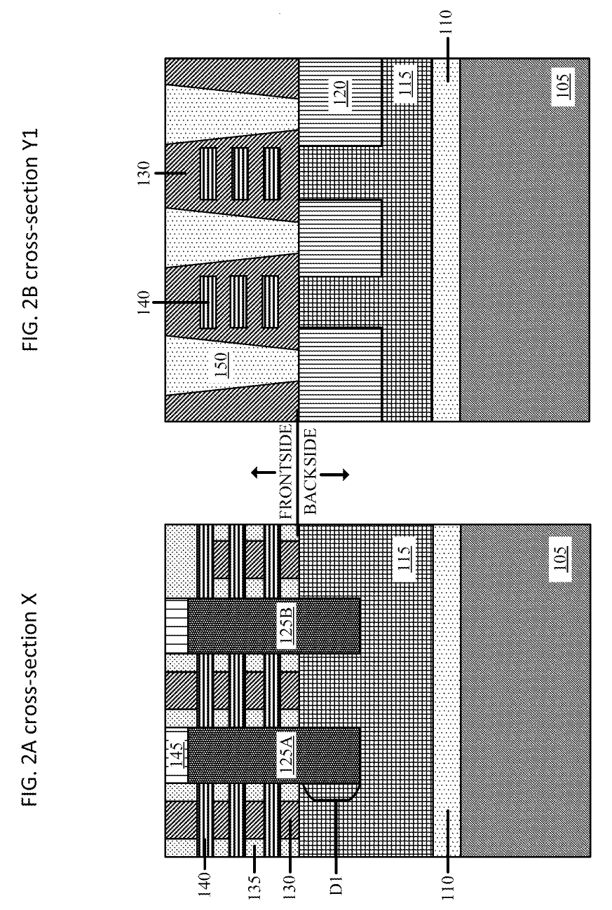

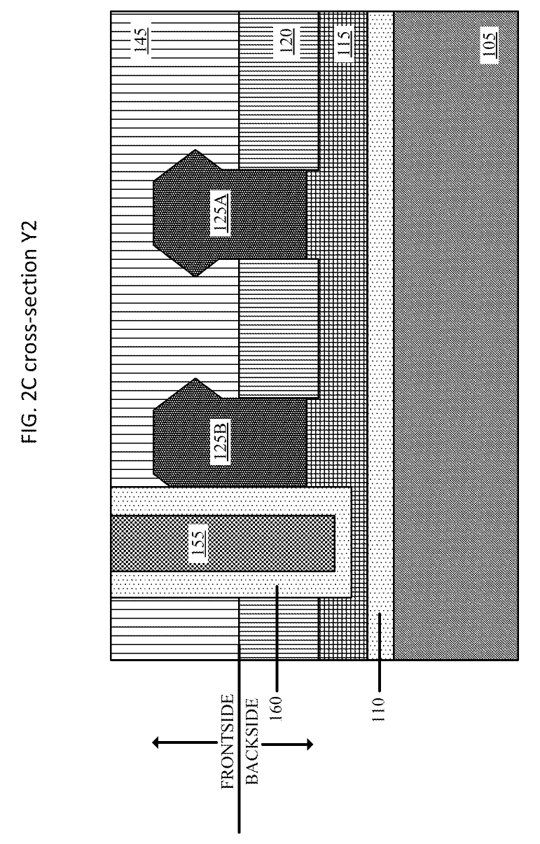

The formation of the microelectronic structure may begin with the formation of the bottom transistor of the stacked FET. FIGS. 2A, 2B, and 2C illustrate cross-sectional views X, Y1, and Y2 of the initial stages of the fabrication process. The microelectronic structure is formed on a first substrate 105. The etch stop 110 is deposited on the first substrate 105, followed by a second substrate 115. The shallow trench isolation layer (STI) 120 is formed within the second substrate 115 to provide electrical isolation between adjacent devices.

The first substrate 105 and the second substrate 115 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 115. In some embodiments, the first substrate 105 and the second substrate 115 include both semiconductor materials and dielectric materials. The first substrate 105 and the second substrate 115 may also be comprised of an organic semiconductor or a layered semiconductor such as, for example, Si/SiGe, a silicon-on-insulator or a SiGe-on-insulator. A portion or the entire first substrate 105 or the second substrate 115 may also be comprised of an amorphous, polycrystalline, or monocrystalline. The first substate 105 and the second substrate 115 may be doped, undoped or contain doped regions and undoped regions therein.

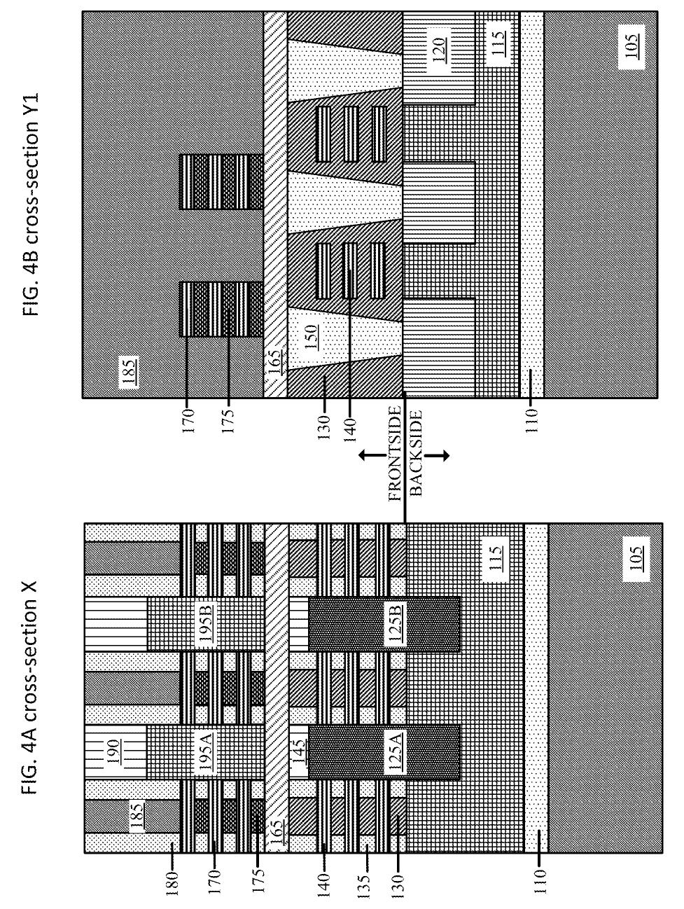

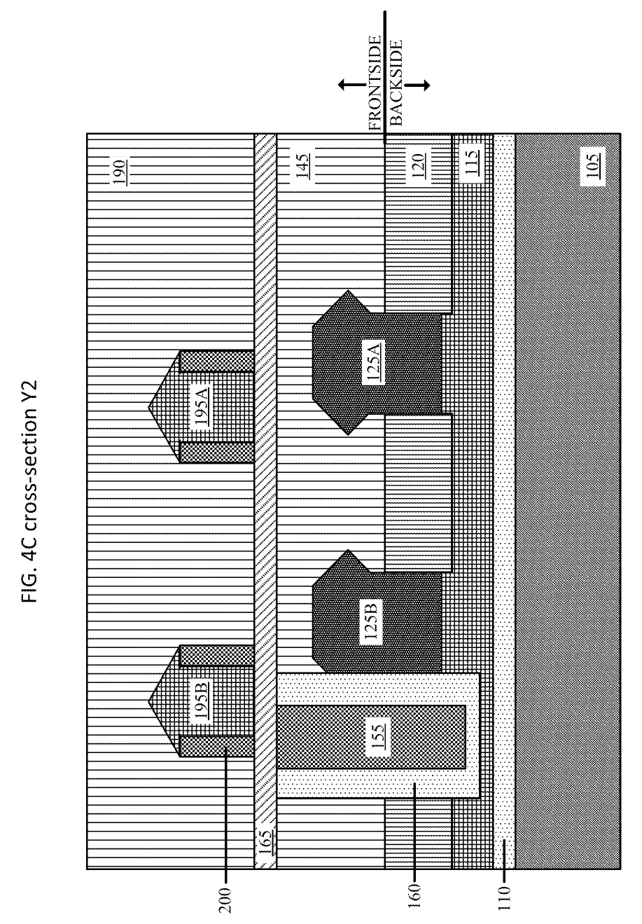

The first lower source/drain 125A (e.g., first backside source/drain 125A, first PFET source/drain 125A) and the second lower source/drain 125B (e.g., second backside source/drain 125B, second PFET source/drain 125B) may be formed and extend downward, deeper than the backside surface of the lower gate 130 into the second substrate 115. The source/drains 125A and 125B can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. In preferred embodiments the first lower source/drain 125A (e.g., first backside source/drain 125A, first PFET source/drain 125A) and the second lower source/drain 125B (e.g., second backside source/drain 125B, second PFET source/drain 125B) may both be PFET. As will be described in greater detail below, in at least FIGS. 4A, 4B, and 4C, the first upper source/drain 195A (e.g., first frontside source/drain 195A, first NFET source/drain 195A) and the second upper source/drain 195B (e.g., second frontside source/drain 195B, second NFET source/drain 195B) may both be NFET. As will be described in greater detail below, the invention enables easier backside contact formation by the lower sources/drains 125A and 125B both being PFET and extending into the second substrate 115.

Lower gate 130 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The material for the lower gate 130 is deposited and patterned to form the gate structure of the bottom/lower transistor by forming inner spacers adjacent to the lower gate 130. Lower channel layers 140 are formed between the lower inner spacers 135, providing the active region for the bottom/lower transistor. The bottom/lower dielectric isolation layer 145 is formed on top of the bottom/lower transistor structure and the lower gate cut(s) 150 is formed through portions of the structure to define individual gate regions.

A lithography layer (not shown) is formed on the bottom/lower dielectric isolation layer 145. The lithography layer and the bottom/lower dielectric isolation layer 145 are etched to form a plurality of trenches (not shown). The via 155 and the via dielectric liner 160 are formed by filling these trenches with material. The via 155 is formed by filling the trench with a conductive material. The via dielectric liner 160 is formed by filling the trench with a dielectric material, or any other suitable material. The via dielectric liner 160 may separate the metal and/or conductive material of the via 155 from the first lower source/drain 125A, providing electrical isolation.

The formation of these initial components, including the bottom/lower transistors and the via 155, may be arranged to facilitate more effective backside contact formation in later stages of the fabrication process. The deeper backside surfaces of the lower sources/drains 125A and 125B extending beyond the backside surface of the lower gate 130 into the second substrate 115, along with the via 155 and via dielectric liner 160 being vertically adjacent to the lower source/drain 125A, may enable for more efficient electrical connections to be made from the backside of the device.

FIGS. 2A-2C illustrate the formation of the lower nanosheet transistor of a stacked FET, which is the closest device to the backside region. The lower transistor is also known as the bottom or lower section of stacked FET when the lower nanosheet transistor and upper nanosheet transistor utilize a shared gate. Therefore, the lower nanosheet transistor or lower section of the stacked FET will also be referred to as the backside section of the stacked nanosheet transistor.

FIG. 2A illustrates a cross-section X of the microelectronic structure prior to initial processing. FIG. 2A illustrates the cross-section X of the microelectronic structure that includes a first substrate 105, the etch stop 110, a second substrate 115, a first lower source/drain 125A, a second lower source/drain 125B, lower gate 130, lower inner spacers 135, lower channel layers 140, and a bottom dielectric isolation layer 145, in accordance with the embodiment of the present invention. The depth of the first lower source/drain 125A and the second lower source/drain 125B is emphasized by brackets D1, the depth D1 of the first lower source/drain 125A and the second lower source/drain 125B extending past the backside most surface of the lower gate 130.

FIG. 2B illustrates a cross-section Y1 of the microelectronic structure prior to initial processing. FIG. 2B illustrates the cross-section Y1 of the microelectronic structure that includes a first substrate 105, the etch stop 110, a second substrate 115, the STI layer 120, lower gate 130, lower channel layers 140, and the lower gate cut(s) 150. The lower gate cut(s) 150 extending from the frontside surface of the lower gate 130 to the frontside surface of the STI layer 120.

FIG. 2C illustrates a cross-section Y2 of the microelectronic structure prior to initial processing. FIG. 2C illustrates the cross-section Y2 of the microelectronic structure that includes a first substrate 105, the etch stop 110, a second substrate 115, the STI layer 120, a first lower source/drain 125A, a second lower source/drain 125B, bottom dielectric isolation layer 145, a via 155, and a via dielectric liner 160. The via 155 and the via dielectric liner being located adjacent to one side of the second source/drain 125B. The via 155 extending downwards passed the backside surface of the first source/drain 125B into the second substrate 115.

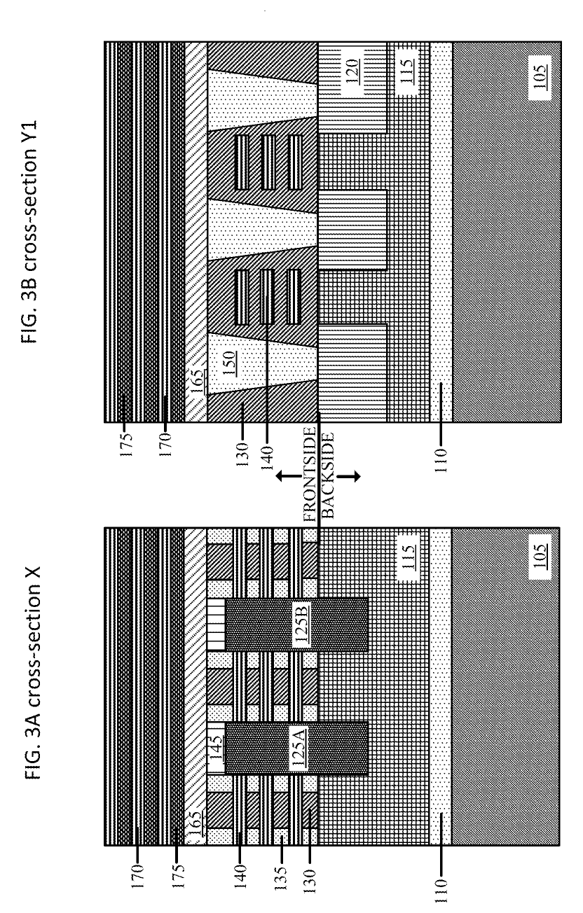

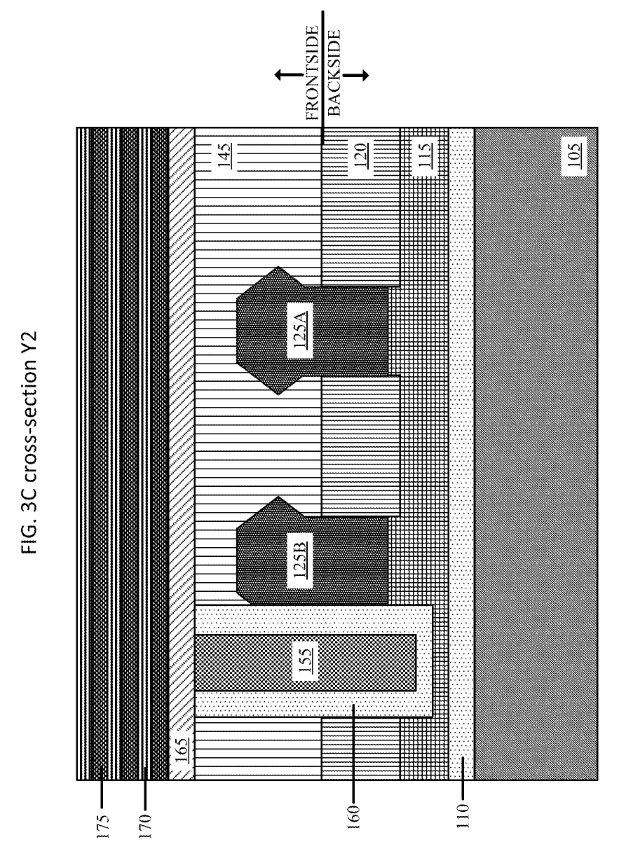

Following the formation of the bottom/lower/backside transistor and the via 155 structures, the process continues with the bonding of top channel materials and the formation of the top/upper/frontside transistor of the microelectronic structure. FIGS. 3A 3B and 3C, illustrates cross-sectional views X, Y1, and Y2 of this stage of the fabrication process. A middle dielectric isolation layer 165 may be formed over the bottom/lower/backside transistor structure. As indicated by the frontside and backside arrows in FIGS. 3A, 3B and 3C. The stacked FET which is formed beginning with the bonding of the top channel materials which include upper channel layers 170 and upper gate placeholder layers 175 formed over the frontside surface of the middle dielectric isolation layer 165.

One of the upper gate placeholder layers 175 may be formed over the frontside surface of the middle dielectric isolation layer 165 followed by one of the upper channel layers 170, another one of the upper gate placeholder layers 175, another one of the upper channel layers 170, a final layer of the upper gate placeholder layers 175, and a final layer of the upper channel layers 170. As will be described in greater detail below, the upper channel layers 170 may provide the active region for the upper/top/frontside transistor. Additionally, the gate placeholder layers may serve as temporary structures that will later be replaced by a final upper gate material.

FIG. 3A illustrates the cross-section X of the microelectronic structure after formation of a middle dielectric isolation layer 165 and bonding of top channel materials including the upper gate placeholder layers 175 and the upper channel layers 170.

FIG. 3B illustrates the cross-section Y1 of the microelectronic structure after formation of a middle dielectric isolation layer 165 and bonding of top channel materials including the upper gate placeholder layers 175 and the upper channel layers 170.

FIG. 3C illustrates the cross-section Y2 of the microelectronic structure after formation of a middle dielectric isolation layer 165 and bonding of top channel materials including the upper gate placeholder layers 175 and the upper channel layers 170.

The formation of the upper/top/frontside transistor of the stacked FET continues in FIGS. 4A-C. FIGS. 4A, 4B and 4C, illustrate cross-sectional views X, Y1, and Y2 of this stage of the fabrication process. The upper channel layers 170 and upper gate placeholder layers 175 undergo active region patterning to define the areas where the upper transistor will be formed. A dummy gate 185 may be formed on top of/on the frontside surface of the upper channel layers 170. The dummy gate 185 acting as a placeholder for the final upper gate structure. Gate spacer formation occurs by upper inner spacers 180 being formed adjacent to each side of the dummy gates 185 and upper gate placeholder layers 175. In some embodiments, a nanosheet recess process may be utilized to create spacer for the formation of the upper inner spacers 180.

Additionally, the formation of the first upper source/drain 195A (e.g., first frontside source/drain 195A, first NFET source/drain 195A) and the second upper source/drain 195B (e.g., second frontside source/drain 195B, second NFET source/drain 195B) is performed. The upper source/drains 195A and 195B being shifted with respect to the lower source/drains 125A and 125B, respectively. The upper source/drains 195A and 195 being confined with upper source/drain spacers 200. The upper source/drain spacers 200 being formed vertically adjacent on each side of each of the upper source/drains 195A and 195B. Similar to the lower source/drains 125A and 125B described in FIG. 2A-C the upper source/drains 195A and 195B can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. In preferred embodiments the first lower source/drain 125A (e.g., first backside source/drain 125A, first PFET source/drain 125A) and the second lower source/drain 125B (e.g., second backside source/drain 125B, second PFET source/drain 125B) may both be PFET and the first upper source/drain 195A (e.g., first frontside source/drain 195A, first NFET source/drain 195A) and the second upper source/drain 195B (e.g., second frontside source/drain 195B, second NFET source/drain 195B) may both be NFET.

An upper dielectric isolation layer 190 is also formed at this stage of the process. The upper dielectric isolation layer 190 is formed on top of the frontside of the upper source/drains 195A and 195B, as shown in FIG. 4A, and surrounds the upper source/drains 195A and 195B and upper source/drain spacers 200 as shown in FIG. 4C extending downward to the frontside surface of the middle dielectric isolation layer 165. Following the formation of the upper dielectric isolation layer 190 chemical mechanical planarization (CMP) is performed to planarize the frontside surface of the upper/top/frontside transistor such that the surface is level with the frontside surface of the dummy gates 185 and upper inner spacers 180, as shown in FIG. 4A.

FIG. 4A illustrates a cross-section X of the microelectronic structure after patterning of the upper channel layers 170 and upper gate placeholder layers 175 and formation of the upper inner spacers 180, a dummy gate 185, an upper dielectric isolation layer 190, a first upper source/drain 195A (e.g., first frontside source/drain 195A, first NFET source/drain 195A), and a second upper source/drain 195B (e.g., second frontside source/drain 195B, second NFET source/drain 195B).

FIG. 4B illustrates a cross-section Y1 of the microelectronic structure after patterning of the upper channel layers 170 and upper gate placeholder layers 175 and formation of the dummy gate 185.

FIG. 4C illustrates a cross-section Y2 of the microelectronic structure after the formation of the first upper source/drain 195A (e.g., first frontside source/drain 195A, first NFET source/drain 195A), a second upper source/drain 195B (e.g., second frontside source/drain 195B, second NFET source/drain 195B), the upper source/drain spacers 200, and the upper dielectric isolation layer 190.

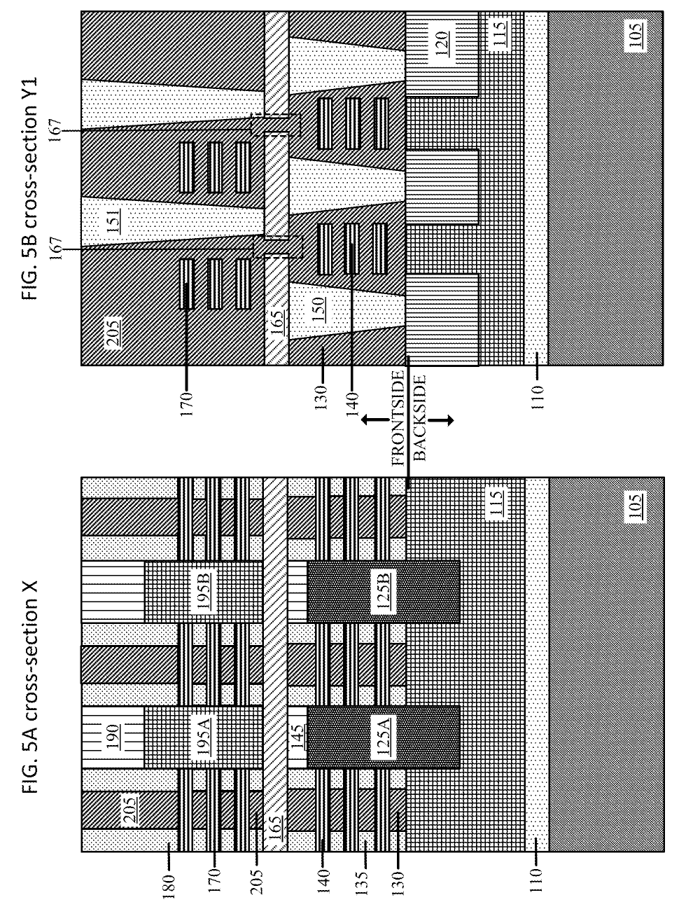

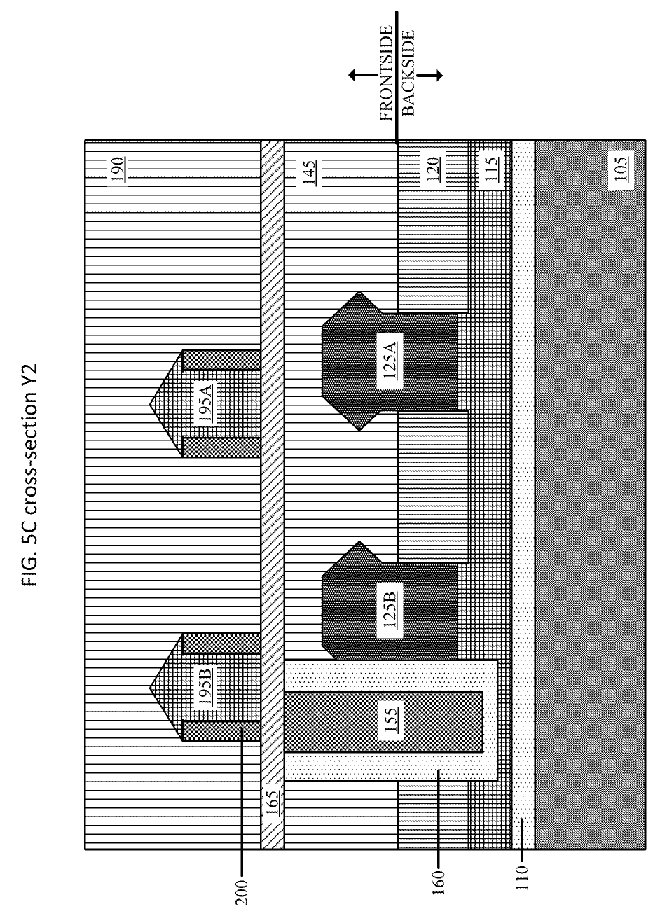

The formation of the upper/top/frontside transistor of the stacked FET continues in FIGS. 5A-C. FIGS. 5A, 5B, and 5C illustrate cross-sectional views X, Y1, and Y2 of this stage of the fabrication process. The dummy gate 185 is removed and a lithography layer/sacrificial SiGe layer (not shown) is formed on the frontside surface of top/upper/frontside transistor over the upper inner spacers 180, the upper dielectric isolation layer 190. The lithography layer (not shown) and the middle dielectric isolation layer 165 are selectively etched to form gate connection openings 167 facilitating electrical connectivity between the NFET active region of the upper/top/frontside transistor and the PFET active region of the lower/bottom/backside transistor. The gate connection openings 167 and the upper gate 205 are then formed by filling these trenches using a replacement metal gate (RMG) process. Similar to the lower gate 130 described in FIG. 2A-C the upper gate 205 and gate connection openings 167 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The formation of the upper gate 205 and gate connection openings confining the first upper source/drain 195A (e.g., first frontside source/drain 195A, first NFET source/drain 195A) and the second upper source/drain 195B (e.g., second frontside source/drain 195B, second NFET source/drain 195B) as shown in FIGS. 5A and 5B. This confinement by the upper inner spacers 180 and upper source/drain spacers 200 contributing to the self-aligned nature of the contacts formed in subsequent steps.

Following the formation of the upper gate 205 another lithography layer (not shown) is formed on the frontside most surface of the upper/top/frontside transistor over the upper inner spacers 180, the upper gate 205, and the upper dielectric isolation layer 190. The lithography layer (not shown) and the upper gate 205 are then etched to form upper gate cuts 151 as shown in FIG. 5B. The upper gate cuts 151 and the lower gate cut(s) 150 defining individual gate regions for the upper and lower transistors, respectively.

FIG. 5A illustrates a cross-section X of the microelectronic structure after removal of the dummy gate 185 and formation of the upper gate 205.

FIG. 5B illustrates a cross-section Y1 of the microelectronic structure after removal of the dummy gate 185 and formation of the upper gate 205, upper gate cut 151, and gate connection openings 167. The lower transistor is also known as the bottom or lower section of stacked FET when the lower nanosheet transistor and upper nanosheet transistor utilize a shared gate, via the gate connection openings 167. Therefore, the lower nanosheet transistor or lower section of the stacked FET will also be referred to as the backside section of the stacked nanosheet transistor.

FIG. 5C illustrates a cross-section Y2 of the microelectronic structure after removal of the dummy gate 185 (not shown in cross-section Y2) and formation of the upper gate 205 (not shown in cross-section Y2).

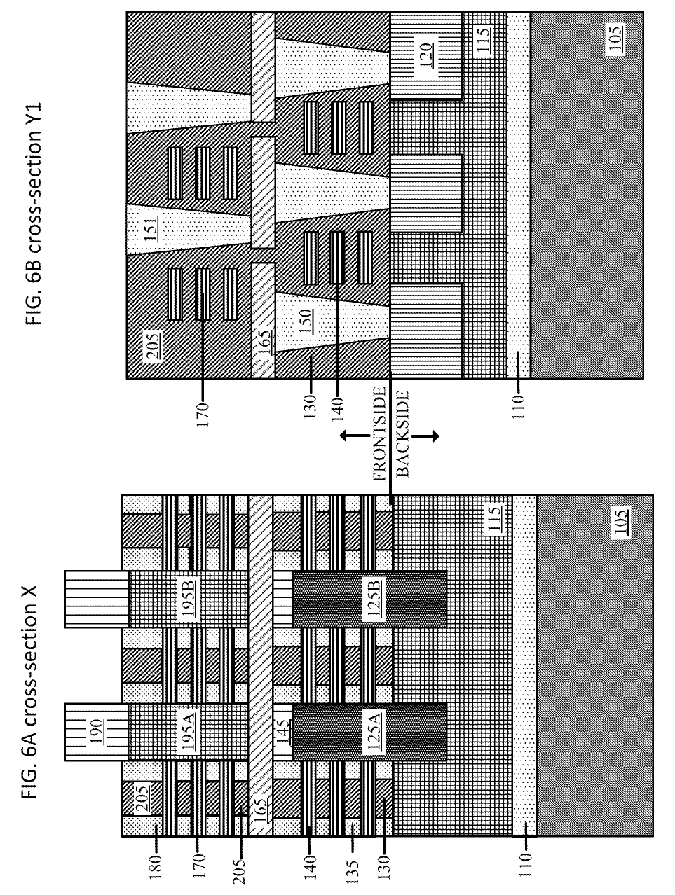

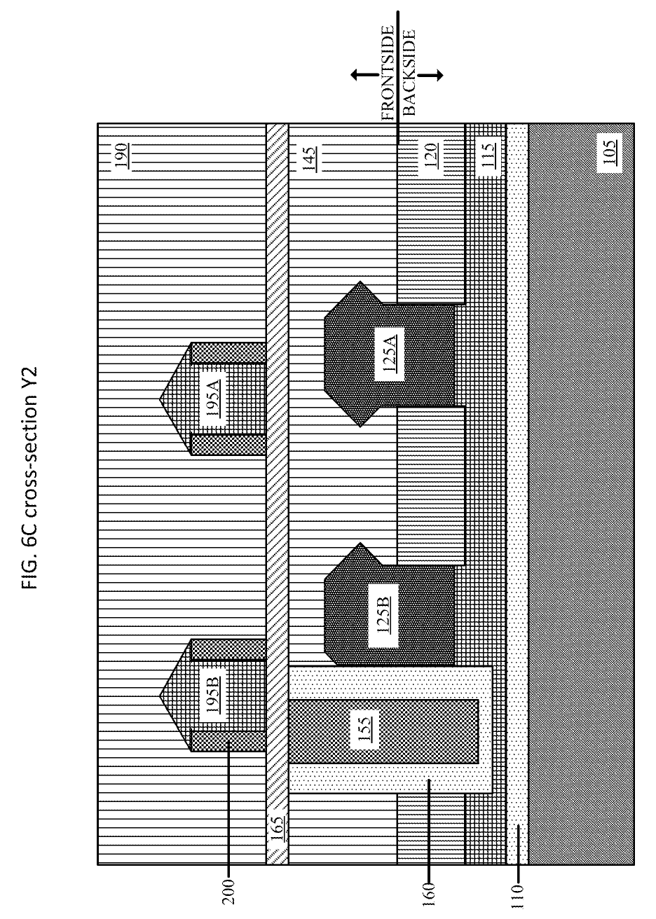

The formation of the upper transistor of the microelectronic structure and frontside processing continues in FIGS. 6A-C. FIGS. 6A, 6B, and 6C illustrate cross-sectional views X, Y1, and Y2 following upper gate 205 and upper inner spacers 180 recess. A lithography layer (not shown) is formed on the frontside surface of the upper/top/frontside transistor over the upper inner spacers 180, upper gate 205, and the upper dielectric isolation layer 190. The lithography layer (not shown) preventing the removal of the upper dielectric isolation layer. The upper gate 205, upper inner spacers 180, and upper gate cuts 151 are pulled down without over-removing by utilizing one or more removal/etching processes to selectively remove portions of the upper gate 205 and upper inner spacers 180 including, but not limited to including, etching process (either wet or dry), reactive ion etching (RIE), chemical-mechanical polishing, amongst other isotropic etching/removal processes.

FIG. 6A illustrates a cross-section X of the microelectronic structure after removal of a portion of the upper gate 205 and upper inner spacers 180.

FIG. 6B illustrates a cross-section Y1 of the microelectronic structure after removal of a portion of the upper gate 205 and upper inner spacers 180.

FIG. 6C illustrates a cross-section Y2 of the microelectronic structure after removal of a portion of the upper gate 205 (not shown in cross-section Y2 perspective) and upper inner spacers 180 (not shown in cross-section Y2 perspective).

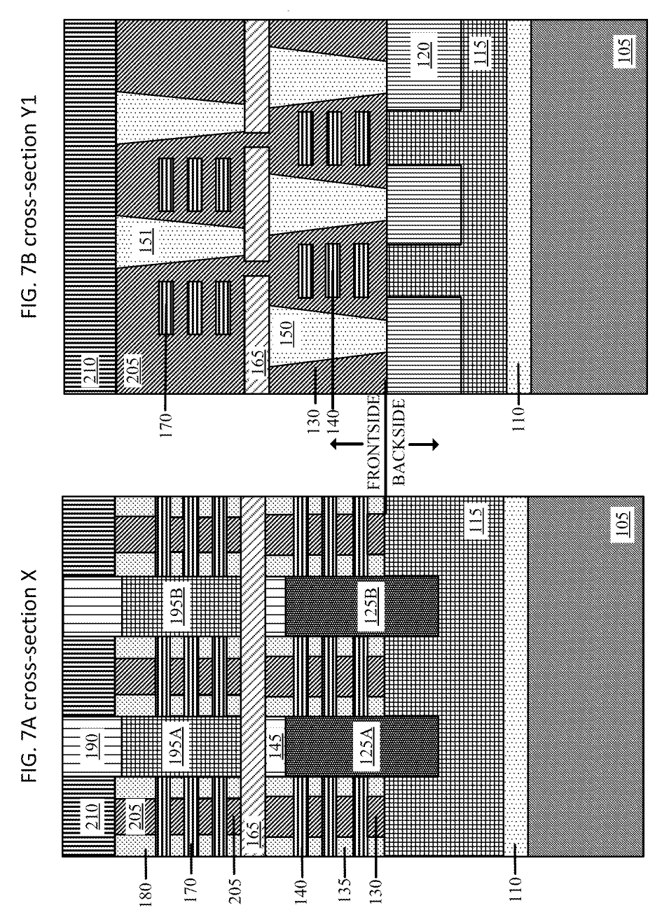

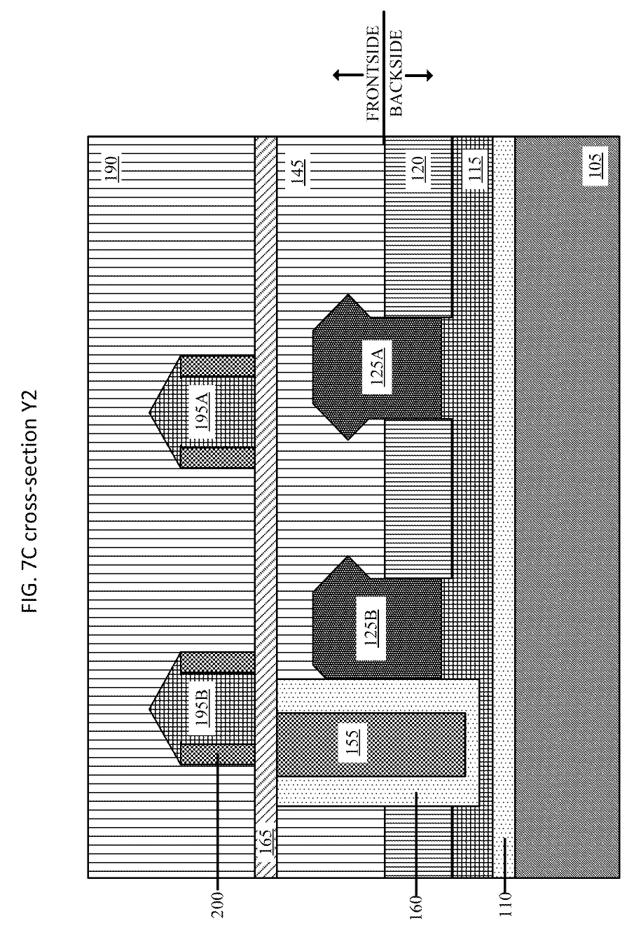

The formation of the upper transistor of the microelectronic structure and frontside processing continues in FIGS. 7A-C. FIGS. 7A, 7B, and 7C illustrate cross-sectional views X, Y1, and Y2 following the formation of a self-aligned contact (SAC) cap 210 (e.g., SAC cap dielectric). The SAC cap 210 is formed on top of the frontside surface of the upper inner spacers 180 and upper gate 205, covering the previously exposed sidewalls of the upper dielectric isolation layer 190 and extending upwards level with the frontside surface of the upper dielectric isolation layer 190, as shown in FIG. 7A. The frontside surface of the SAC cap 210 and the frontside surface of the upper dielectric isolation layer 190 may be similar following chemical mechanical planarization (CMP). Additionally, as shown in FIG. 7B the SAC cap 210 is formed on the top of the upper gate 205 and upper gate cuts 151.

The SAC cap 210 is comprised of dielectric material that is different from the material used for the upper inner spacers 180. As will be described in subsequent steps of the fabrication process, this difference in materials enables selective etching between the SAC cap 210 and the upper inner spacers 180.

FIG. 7A illustrates a cross-section X of the microelectronic structure after formation of a self-aligned contact (SAC) cap 210.

FIG. 7B illustrates a cross-section Y1 of the microelectronic structure after formation of a self-aligned contact (SAC) cap 210.

FIG. 7C illustrates a cross-section Y2 of the microelectronic structure after formation of a self-aligned contact (SAC) cap 210 (not shown in the cross-section Y2 perspective).

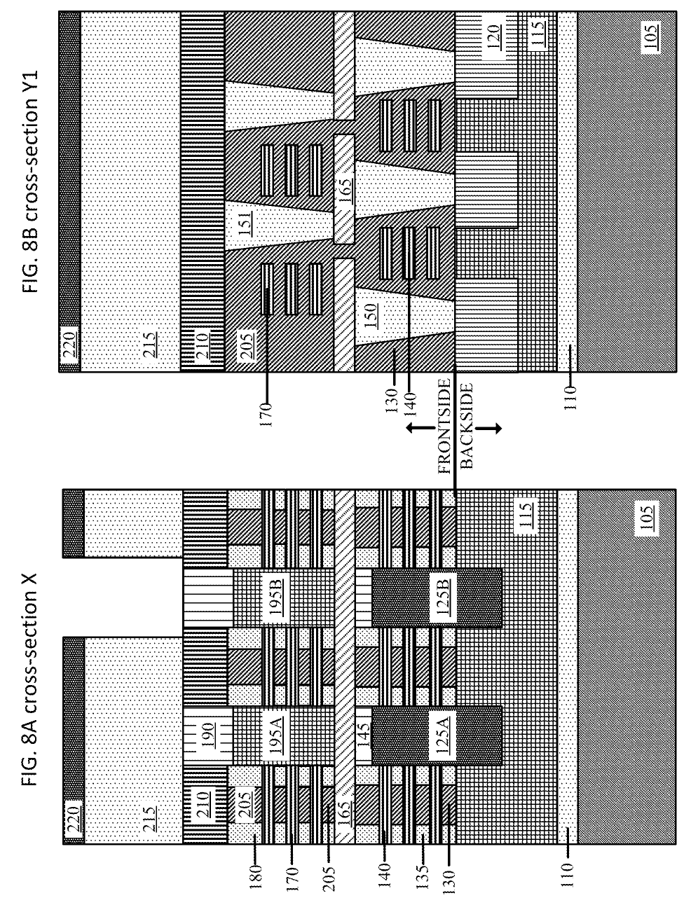

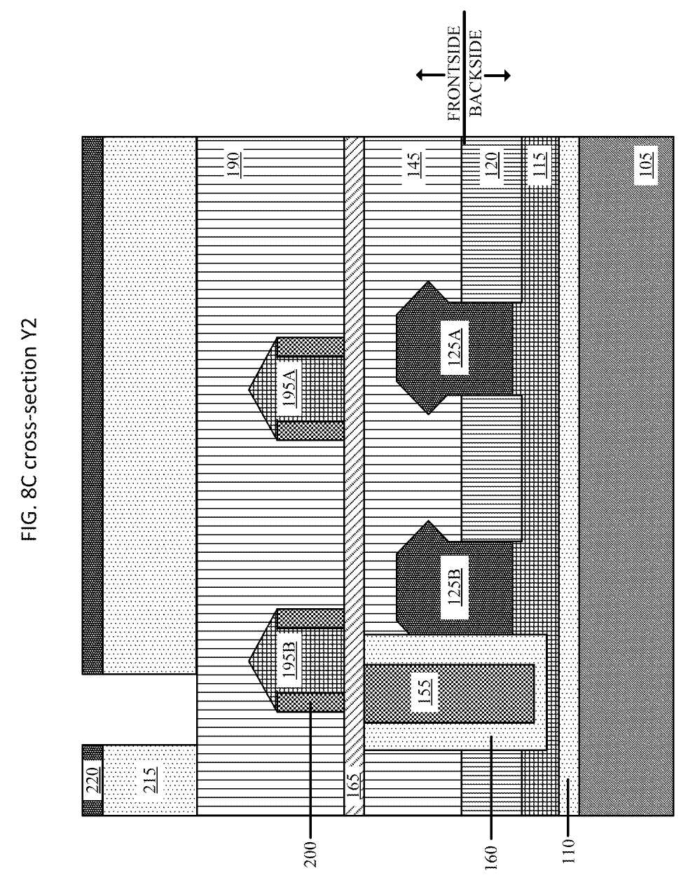

The formation of the upper/top/frontside transistor and frontside processing of the stacked FET continues in FIGS. 8A-C. FIGS. 8A, 8B, and 8C illustrate cross-sectional views X, Y1, and Y2 of after sidewall contact patterning. A lithography layer/sacrificial protection layer 215 is formed on the frontside surface of the upper/top/frontside transistor on the frontside surfaces of the SAC cap 210 and the upper gate 205. A SiARC layer 220 is formed on the frontside surface of the lithography layer/sacrificial protection layer 215. The lithography layer/sacrificial protection layer 215 and the SiARC layer 220 are then etched exposing a frontside surface of the upper dielectric isolation layer 190, the upper dielectric isolation layer 190 covering the frontside surface of the second upper source/drain 195B (e.g., second frontside source/drain 195B, second NFET source/drain 195B), as shown in FIGS. 8A and 8C.

FIG. 8A illustrates a cross-section X of the microelectronic structure after the formation of a lithography layer 215 and SiARC layer 220 and removal of portions of the lithography layer 215 and the SiARC layer 220 exposing a frontside surface of the upper dielectric isolation layer 190, the upper dielectric isolation layer 190 covering the frontside surface of the second upper source/drain 195B (e.g., second frontside source/drain 195B, second NFET source/drain 195B).

FIG. 8B illustrates a cross-section Y1 of the microelectronic structure after the formation of a lithography layer 215 and SiARC layer 220, portions of the lithography layer and the SiARC layer 220 are removed but not shown in the cross-section Y1 perspective.

FIG. 8C illustrates a cross-section Y2 of the microelectronic structure after the formation of a lithography layer 215 and SiARC layer 220 and removal of portions of the lithography layer 215 and the SiARC layer 220 exposing a frontside surface of the upper dielectric isolation layer 190, the upper dielectric isolation layer 190 covering the frontside surface of the second upper source/drain 195B (e.g., second frontside source/drain 195B, second NFET source/drain 195B).

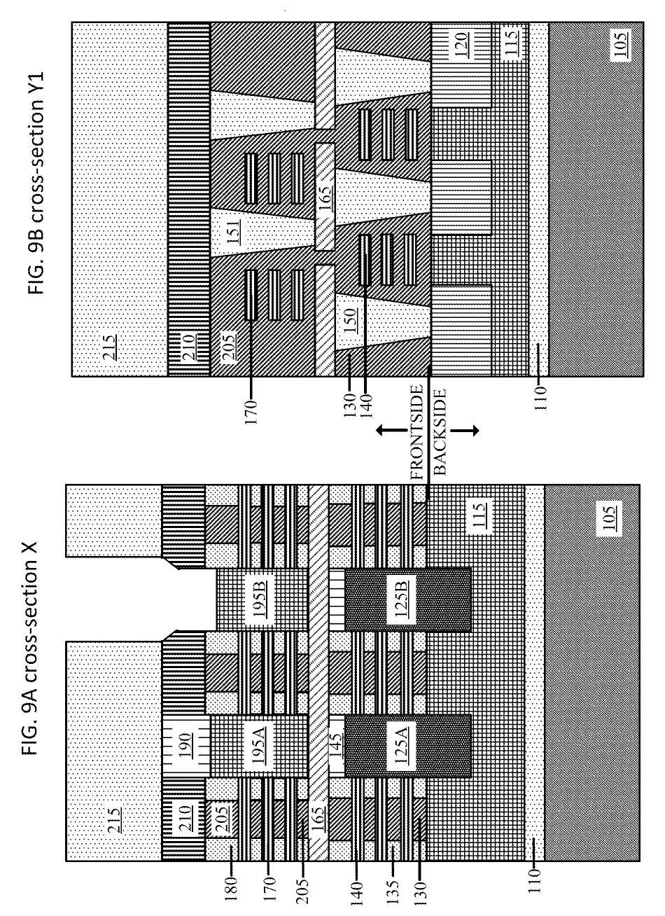

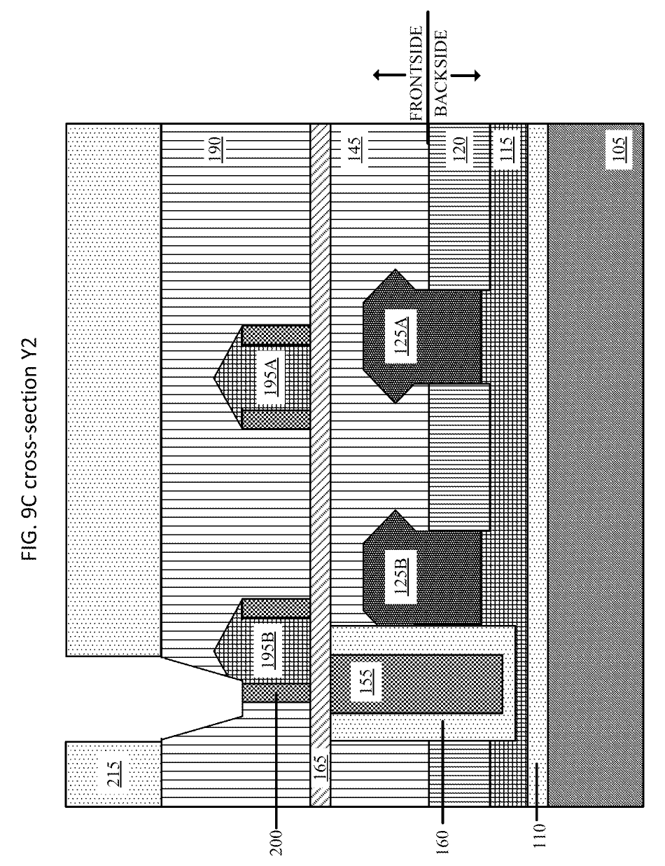

Frontside processing of the microelectronic structure continues at FIGS. 9A-C. FIGS. 9A, 9B, and 9C illustrate cross-sectional views X, Y1, and Y2 following a sidewall contact reactive ion etching (RIE) process performed to create contact trenches with the second upper source/drain 195B (e.g., second frontside source/drain 195B, second NFET source/drain 195B), as shown in FIGS. 9A and 9C.

FIG. 9A illustrates a cross-section X of the microelectronic structure after the removal of SiARC layer 220, a portion of the SAC cap 210, and a frontside portion of the second upper source/drain 195B (e.g., second frontside source/drain 195B, second NFET source/drain 195B).

FIG. 9B illustrates a cross-section Y1 of the microelectronic structure after removal of the SiARC layer 220, the portion of the SAC cap 210 and the frontside portion of the second upper source/drain 195B (e.g., second frontside source/drain 195B, second NFET source/drain 195B) are not shown in the cross-section Y1 perspective.

FIG. 9C illustrates a cross-section Y2 of the microelectronic structure after removal of the SiARC layer 220 and removal of a frontside portion of the second upper source/drain 195B (e.g., second frontside source/drain 195B, second NFET source/drain 195B), the removal of a portion of the SAC cap 210 is not shown in the cross-section Y2 perspective.

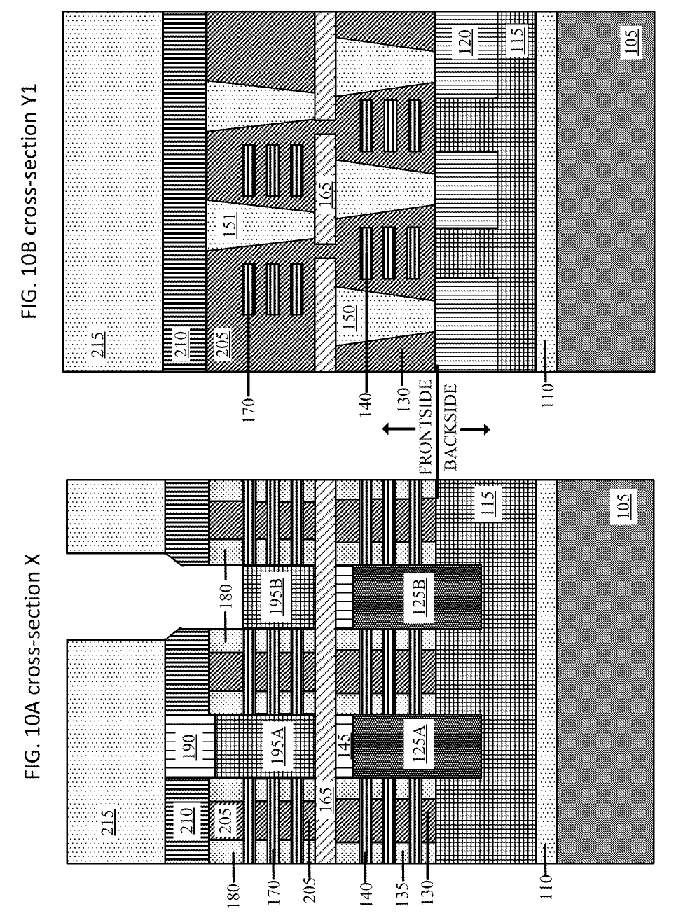

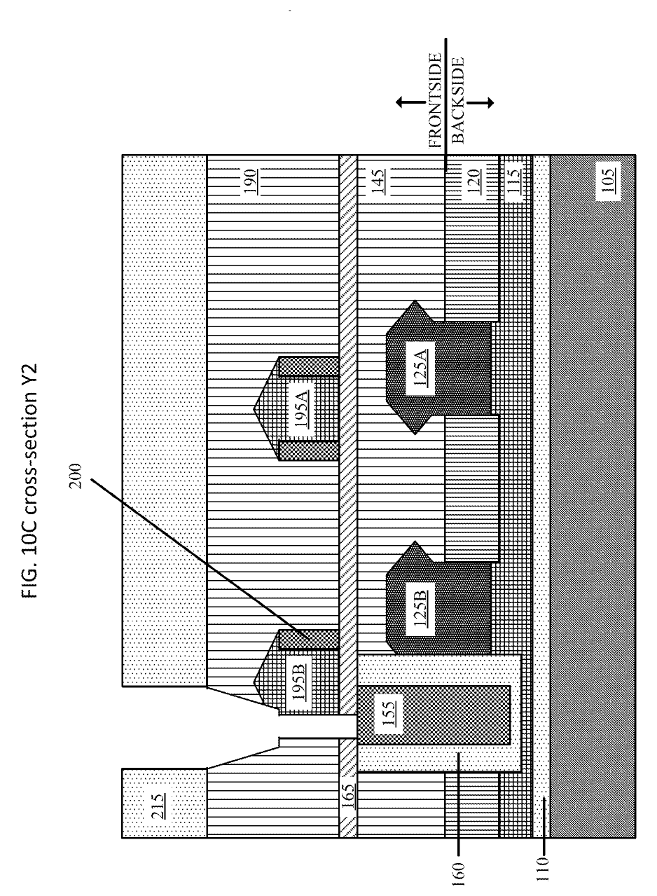

Frontside processing of the microelectronic structure continues at FIGS. 10A-C. FIGS. 10A, 10B, and 10C illustrate cross-sectional views X, Y1, and Y2 following selective dielectric reactive ion etching (RIE). The RIE being selective to the SAC cap 210. The SAC cap 210 allows for this selective spacer RIE process to be performed without damaging upper inner spacers 180, as shown in FIG. 10A exposing a frontside surface of the second upper source/drain 195B (e.g., second frontside source/drain 195B, second NFET source/drain 195B). One of the upper source/drain spacers 200 is also selectively removed during the RIE process, exposing a sidewall of the second upper source/drain 195B (e.g., second frontside source/drain 195B, second NFET source/drain 195B) and extending the trench formed in FIGS. 9A-c downwards through the middle dielectric isolation layer 165 to the frontside of the via 155.

FIG. 10A illustrates a cross-section X of the microelectronic structure exposing a frontside surface of the second upper source/drain 195B (e.g., second frontside source/drain 195B, second NFET source/drain 195B) by performed a selective RIE process without damaging the upper inner spacers 180.

FIG. 10B illustrates a cross-section Y1 of the microelectronic structure after performing the selective RIE process, the trench formed at this step of the frontside fabrication process is not shown in the cross-section Y1 perspective.

FIG. 10C illustrates a cross-section Y2 of the microelectronic structure after removal of one of the upper source/drain spacers 200 from one side of the second upper source/drain 195B (e.g., second frontside source/drain 195B, second NFET source/drain 195B) extending the trenches formed in FIGS. 8 and 9 downwards through the middle dielectric isolation layer 165 to the frontside of the via 155.

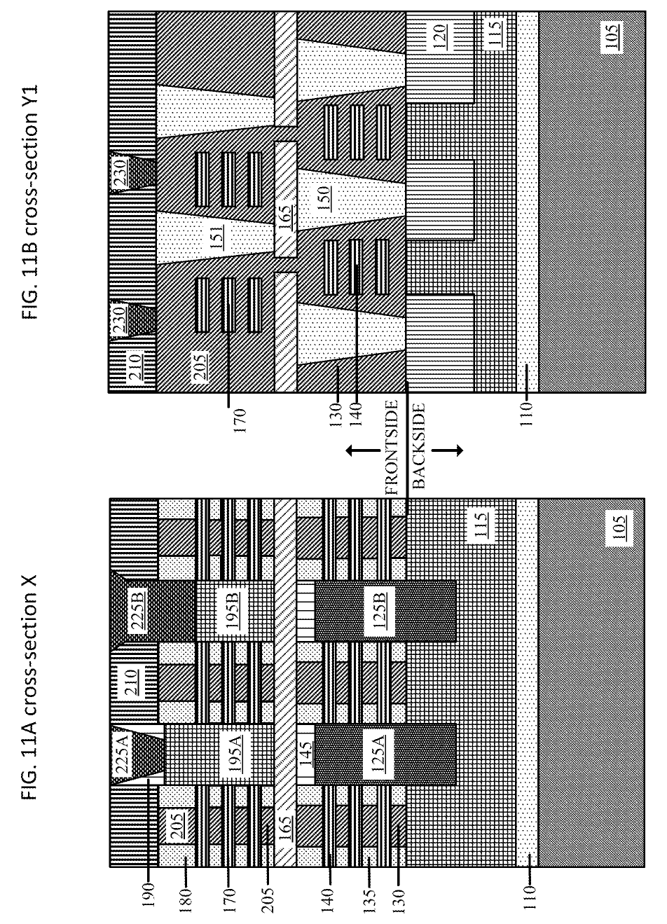

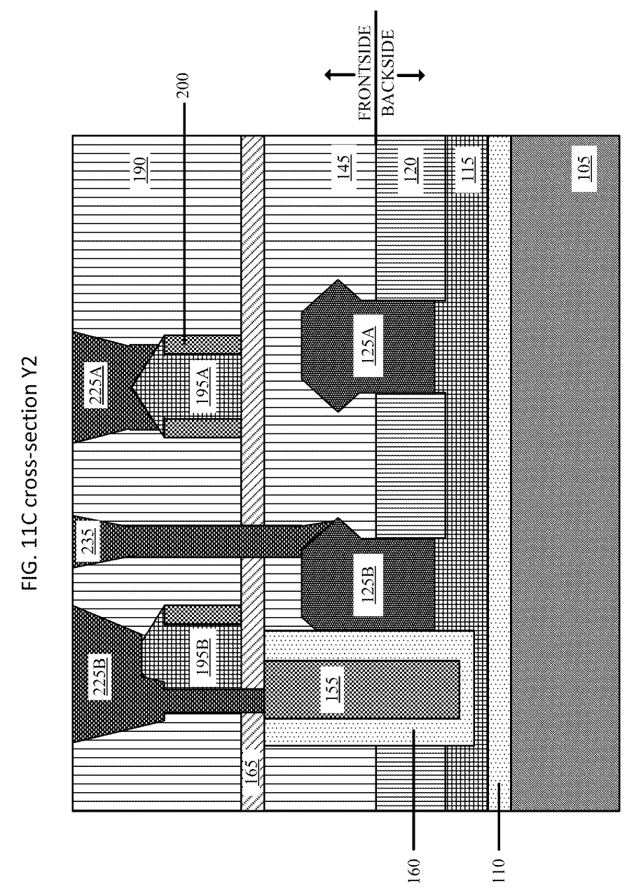

The frontside fabrication process of the upper transistor continues at FIGS. 11A-C. FIGS. 11A, 11B, and 11C illustrate cross-sectional views X, Y1, and Y2 following the removal of the lithography layer 215 and the metallization process. The removal of lithography layer 215 is performed using an ashing process (e.g., plasma ashing), the removal of the lithography layer 215 prepares the top/upper/frontside transistor for metallization and contact formation. The formation of the trenches and selective etching processes performed in FIGS. 8, 9, and 10 created pathways for electrical connections to both the upper and lower transistor components. The exposure of the via 155 enabling subsequent contact formation to connect the upper source/drains 195A and 195B with the lower device layers.

In addition to the trench formation and etching processes described in FIGS. 8, 9, and 10, additional patterning is performed in FIGS. 11A-C for the upper source/drain contacts 225, upper gate contacts 230, lower source/drain contact 235 and middle of the line (MOL) metallization. Upper source/drain contact 225B (e.g., self-aligned sidewall contact 225B) formed by filling the trenches formed in FIGS. 8, 9, and 10 with a conductive metal. As shown in FIG. 11C, the metallization of the previously formed trenches directly connects the upper source/drain contact 225B (e.g., self-aligned sidewall contact 225B) to the via 155, as will be described in later figures, which will enable subsequent contact formation to connect the upper source/drains 195A, 195B, with the lower device layers.

The additional patterning for the upper source/drain contact 225A, upper gate contacts 230, and the lower source/drain contact 235 may involve any of the etching/removal processes previously described to form trenches with the use of lithography layers and/or sacrificial protection layers (not shown). The upper source/drain contact 225A being formed following metallization of a trench (not shown) formed in the upper dielectric isolation layer 190, as shown in FIGS. 11A and 11C. The upper gate contacts 230 being formed following the metallization of trenches (not shown) formed in the SAC cap 210, as shown in FIG. 11B. The lower source/drain contact 235 being formed following metallization of a trench (not shown) formed through the upper dielectric isolation layer 190, the middle dielectric isolation layer 165, and the bottom/lower dielectric isolation layer 145, as shown in FIG. 11C. The lower source/drain contact 235 being in contact with the second lower source/drain 125B (e.g., second backside source/drain 125B, second PFET source/drain 125B). The lower source/drain contact 235 being on the opposite side of the via 155 and via dielectric liner 160, as shown in FIG. 11C.

FIG. 11A illustrates a cross-section X of the microelectronic structure after formation of the upper source/drain contacts 225.

FIG. 11B illustrates a cross-section Y1 of the microelectronic structure after formation of the upper gate contacts 230.

FIG. 11C illustrates a cross-section Y2 of the microelectronic structure after formation of the upper source/drain contacts 225 and the first lower source/drain contact 235.

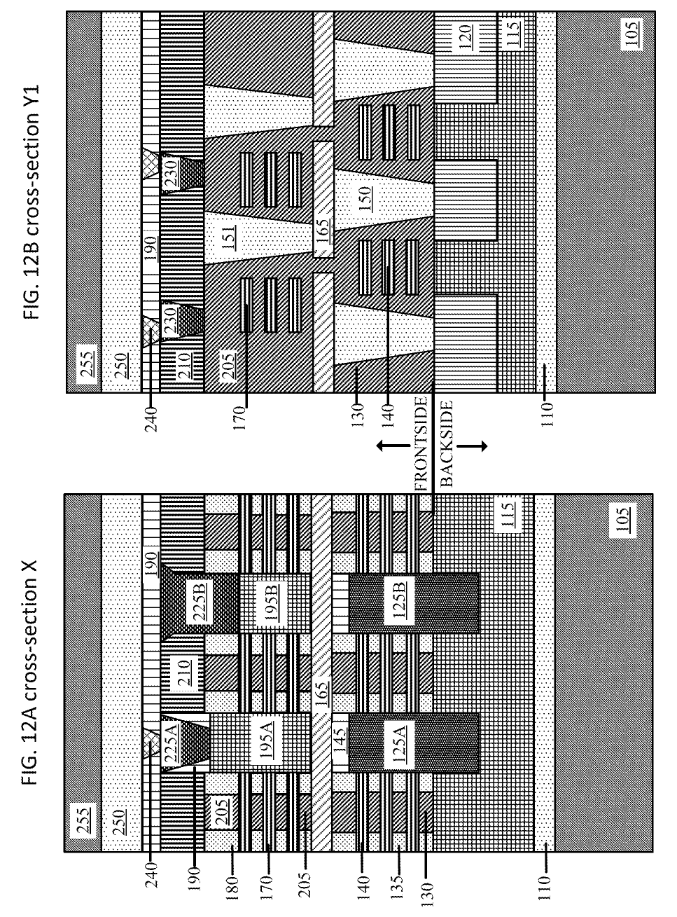

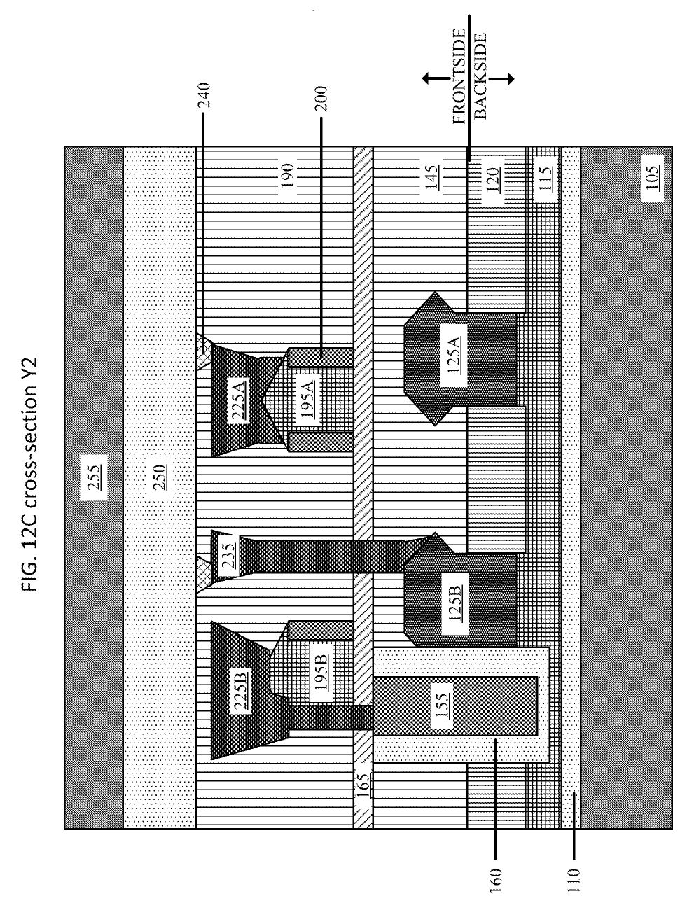

The final steps of frontside processing are illustrated in FIGS. 12A-C. FIGS. 12A, 12B, and 12C illustrate cross-sectional views X, Y1, and Y2 following the formation of the back end of line (BEOL) layer 250 and carrier wafer 255. The upper dielectric isolation layer 190 height is extended over the top of the frontside surfaces of the SAC cap 210, the upper source/drain contacts 225A and 225B, the lower source drain/contact 235, and the upper gate contacts 230, as shown in FIGS. 12A-C. The upper dielectric isolation layer 190 is formed on the frontside surfaces of the SAC cap 210, upper source/drain contacts 225, and the upper gate contacts 230, as shown in FIGS. 12A and 12B. The upper dielectric isolation layer 190 height extension covering the frontside surfaces of upper source/drain contact 225A, lower source/drain contact 235, and upper source/drain contact 225B, as shown in FIG. 12C. A lithography layer (not shown) may then be formed on the frontside surface of the upper dielectric isolation layer 190. The lithography layer (not shown) and the upper dielectric isolation layer 190 are then patterned to form a plurality of plurality of trenches (not shown) within the upper dielectric isolation layer 190. The plurality of metal line(s) 240 or metal track(s) 240 are formed by filling these trenches with a conductive metal. The plurality of metal line(s) 240 or metal track(s) 240 may be utilized for a plurality of purposes, such as, but not limited to, power, signal communication, ground, clock, amongst other purposes.

The BEOL layer 250 is formed over the frontside surface of the plurality of metal line(s) 240 or metal track(s) 240 and the frontside surface of the upper dielectric isolation layer 190. A carrier wafer 255 is then formed over the frontside surface of the BEOL layer 250.

FIG. 12A illustrates a cross-section X of the microelectronic structure after formation of the upper dielectric isolation layer 190, a plurality of metal line(s) 240 or metal track(s) 240, BEOL layer 250, and the carrier wafer 255.

FIG. 12B illustrates a cross-section Y1 of the microelectronic structure after formation of the upper dielectric isolation layer 190, a plurality of metal line(s) 240 or metal track(s) 240, BEOL layer 250, and the carrier wafer 255.

FIG. 12C illustrates a cross-section Y2 of the microelectronic structure after formation of the upper dielectric isolation layer 190, a plurality of metal line(s) 240 or metal track(s) 240, BEOL layer 250, and the carrier wafer 255.

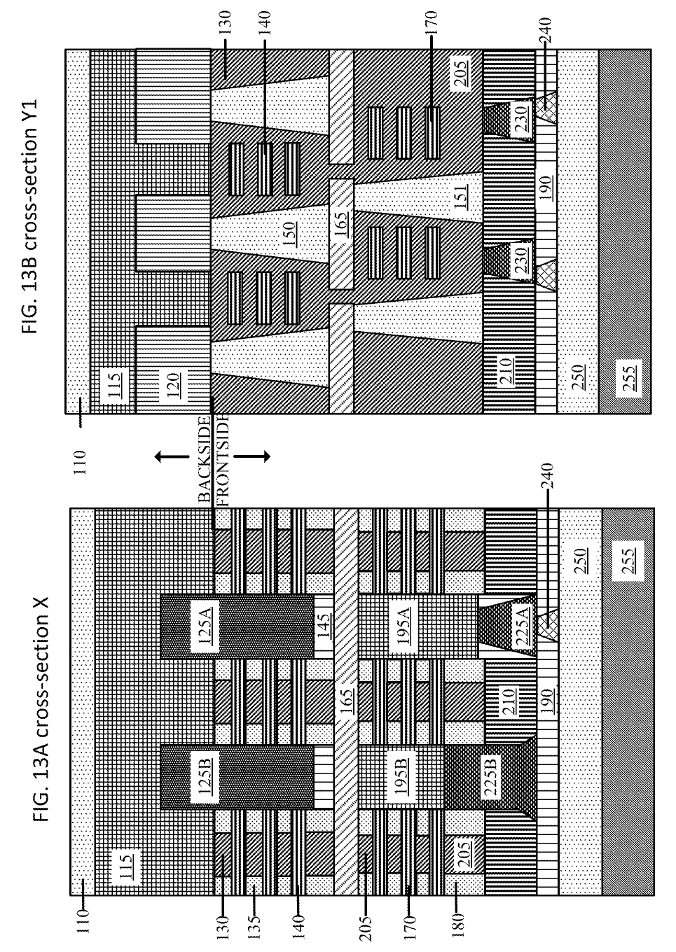

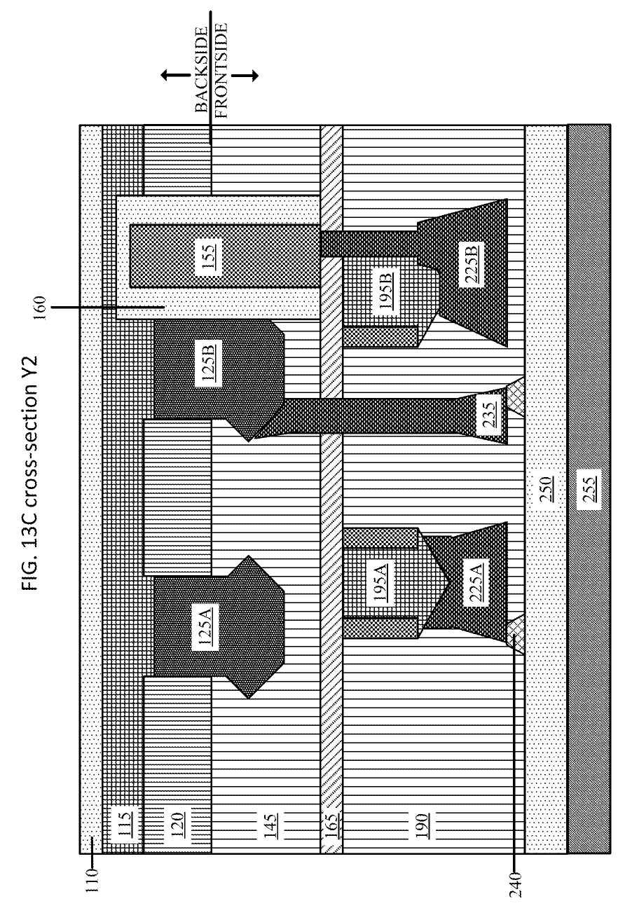

FIGS. 13-16 illustrate the processing stage after flipping the microelectronic structure over for backside processing. Carrier wafer 255 allows for the microelectronic structure (nanosheet transistor, logic device, or logic device with a passive device) to be flipped over for backside processing, i.e., flipping over the microelectronic structure exposes the backside region of the device. FIGS. 2-12 illustrated the frontside processing of the microelectronic structure and FIGS. 13-16 illustrate the backside processing of the microelectronic structure.

Backside processing of the microelectronic structure begins in FIGS. 13A-C. FIGS. 13A, 13B, 13C, illustrate cross-sectional views X, Y1, and Y2 after the microelectronic structure is flipped over, using the carrier wafer 255, as indicated by the change in the backside and frontside directional arrows from FIGS. 12A-C to FIGS. 13A-C. Following the carrier wafer 255 flip the first substrate 105 is removed. The removal of the first substrate stopping at the etch stop 110.

FIG. 13A illustrates a cross-section X of the microelectronic structure after flipping of the device over for backside processing and after first substrate 105 removal.

FIG. 13B illustrates a cross-section Y1 of the microelectronic structure after flipping of the device over for backside processing and after first substrate 105 removal.

FIG. 13C illustrates a cross-section Y2 of the microelectronic structure after flipping of the device over for backside processing and after first substrate 105 removal.

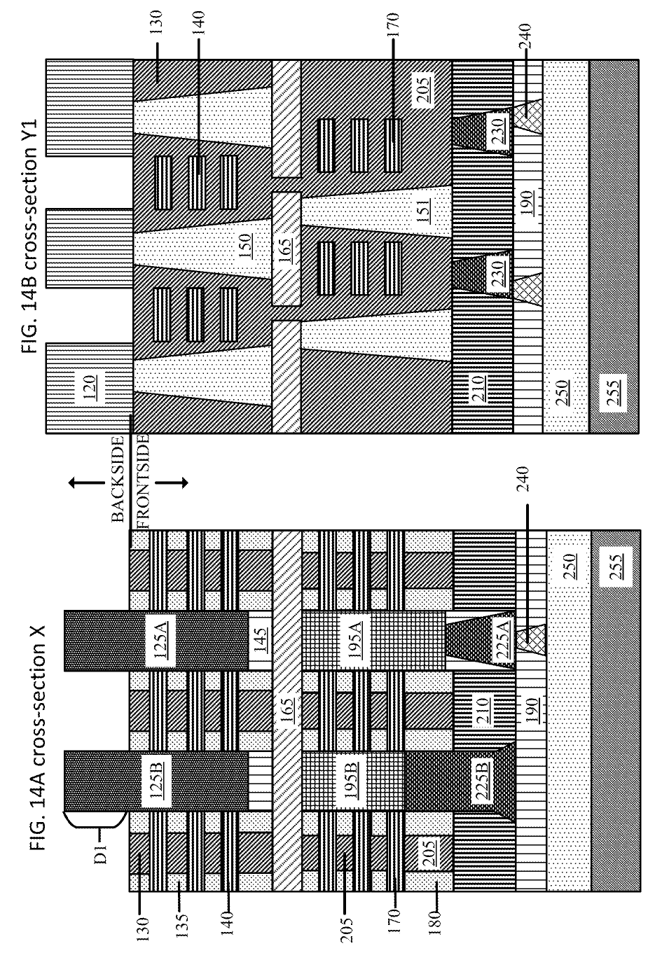

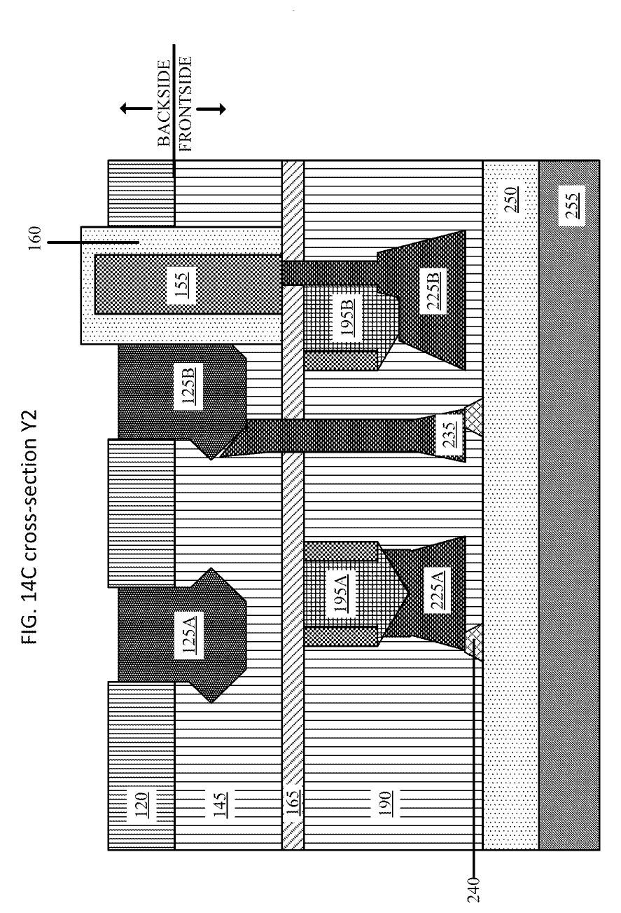

Backside processing of the microelectronic structure continues in FIGS. 14A-C. FIGS. 14A, 14B, and 14C illustrate cross-sectional views X, Y1, and Y2 following the etch stop 110 and second substrate 115 removal.

FIG. 14A illustrates a cross-section X of the microelectronic structure after removal of the etch stop 110 and the second substrate 115. The removal of the second substrate exposing a portion of the first lower source/drain 125A (e.g., first backside source/drain 125A, first PFET source/drain 125A) and second lower source/drain 125B (e.g., second backside source/drain 125B, second PFET source/drain 125B). The portion of the first lower source/drain 125A (e.g., first backside source/drain 125A, first PFET source/drain 125A) and second lower source/drain 125B (e.g., second backside source/drain 125B, second PFET source/drain 125B) being the depth D1 previously shown in FIG. 2A. The depth D1 being the backside extension of the lower source/drains 125 beyond a backside surface of the lower gate 130 and lower inner spacers 135. The backside surfaces of the lower gate 130 and the lower inner spacers 135 being exposed following second substrate 115 removal.

FIG. 14B illustrates a cross-section Y1 of the microelectronic structure after removal of the etch stop 110 and the second substrate 115. The removal of the second substrate 115 exposing the backside and side surfaces of the STI layer 120 and portions of the backside surface of the lower gate 130.

FIG. 14C illustrates a cross-section Y2 of the microelectronic structure after removal of the etch stop 110 and the second substrate 115. The removal of the second substrate 115 exposing the backside surfaces of the first lower source/drain 125A (e.g., first backside source/drain 125A, first PFET source/drain 125A), second lower source/drain 125B (e.g., second backside source/drain 125B, second PFET source/drain 125B), the STI layer 120, and the via dielectric liner 160. The removal of the second substrate 115 also exposing side portions of the STI layer 120 and via dielectric liner 160.

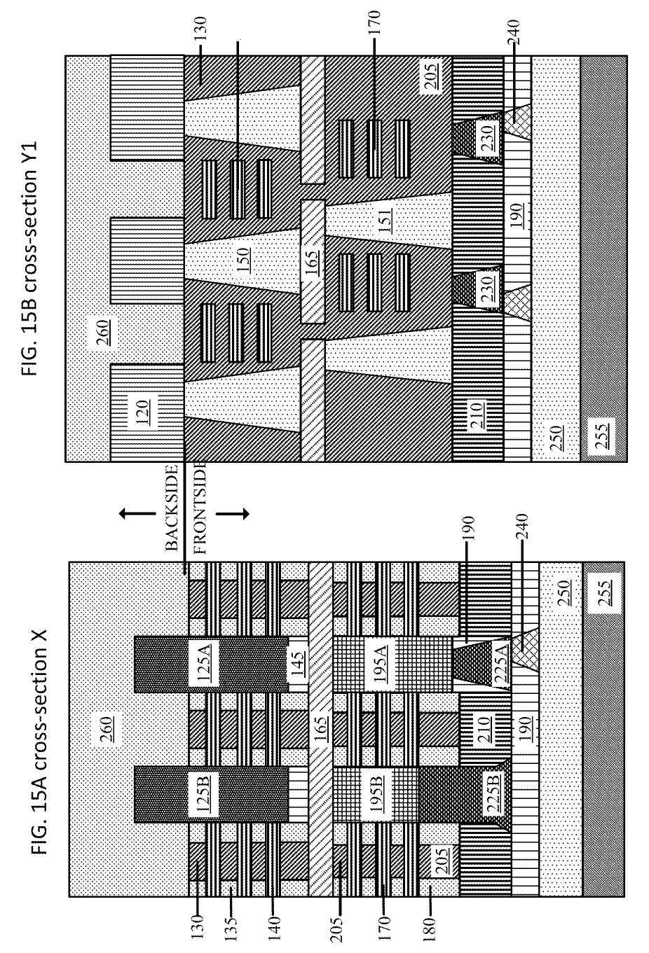

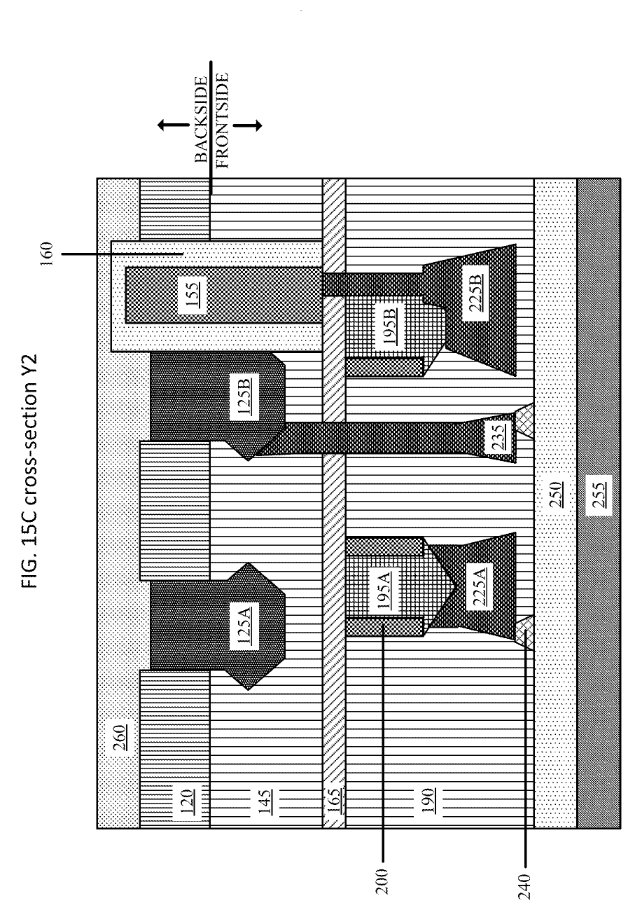

Backside processing of the microelectronic structure continues in FIGS. 15A-C. FIGS. 15A, 15B and 15C illustrate cross-sectional views X, Y1, and Y2 following backside interlayer dielectric layer (BILD) 260 formation.

FIG. 15A illustrates a cross-section X of the microelectronic structure after formation of the BILD 260 formation. In FIG. 15A the BILD 260 is formed over the previously exposed backside surfaces of the lower gate 130, the lower inner spacers 135, and the lower source/drains 125. The BILD 260 also covers the previously exposed side portions of the first lower source/drain 125A (e.g., first backside source/drain 125A, first PFET source/drain 125A) and the second lower source/drain 125B (e.g., second backside source/drain 125B, second PFET source/drain 125B).

FIG. 15B illustrates a cross-section Y1 of the microelectronic structure after formation of the BILD 260. In FIG. 15B the BILD 260 is formed over the previously exposed portions of the backside and side surfaces of the STI layer 120 and portions of the backside surface of the lower gate 130.

FIG. 15C illustrates a cross-section Y2 of the microelectronic structure after formation of the BILD 260. In FIG. 15C the BILD 260 is formed over the previously exposed portions of the backside surfaces of the first lower source/drain 125A (e.g., first backside source/drain 125A, first PFET source/drain 125A), second lower source/drain 125B (e.g., second backside source/drain 125B, second PFET source/drain 125B), the STI layer 120, and the via dielectric liner 160. The BILD also covers the previously exposed side portions of the STI layer 120 and via dielectric liner 160.

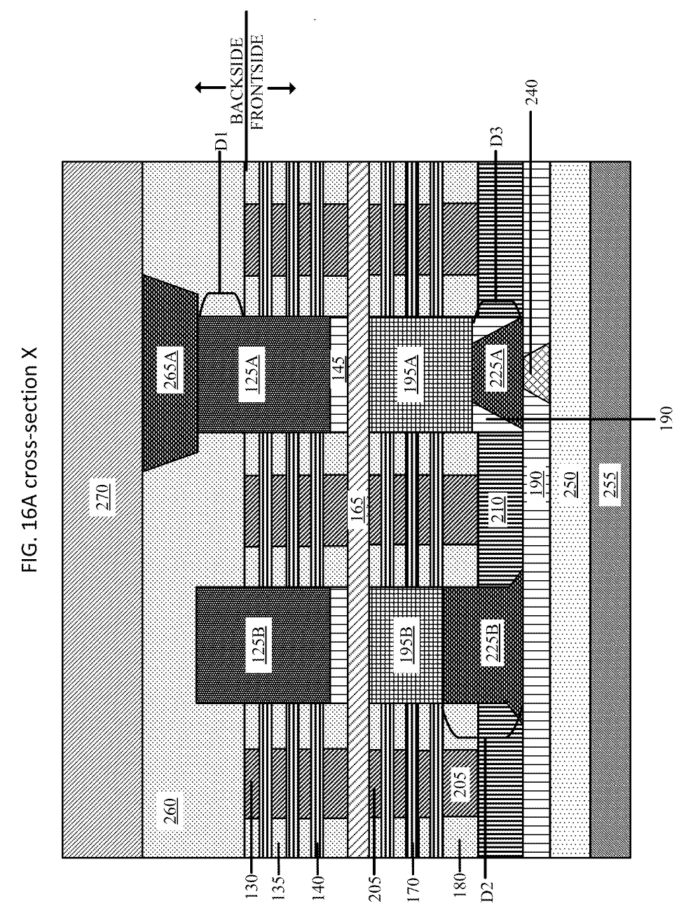

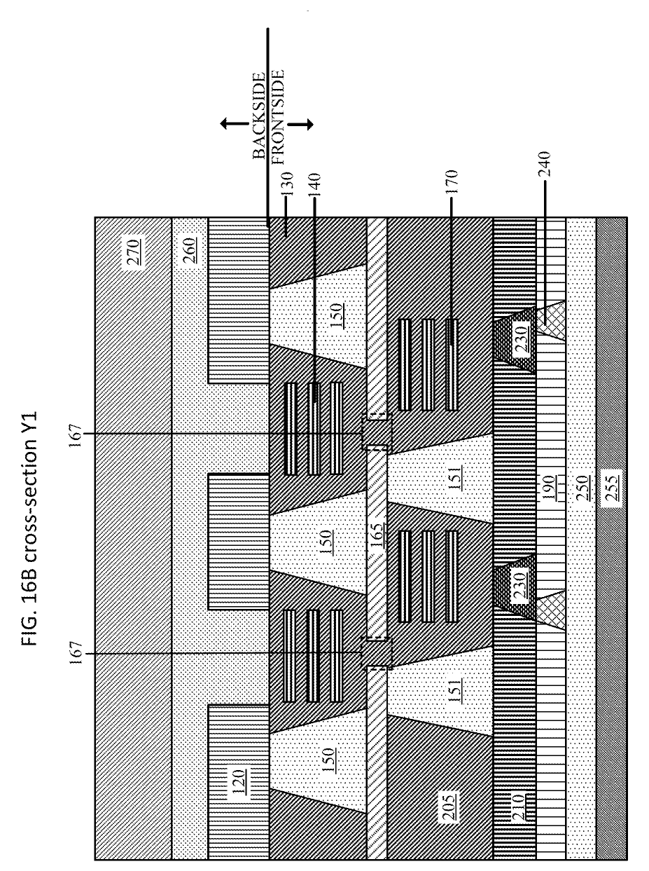

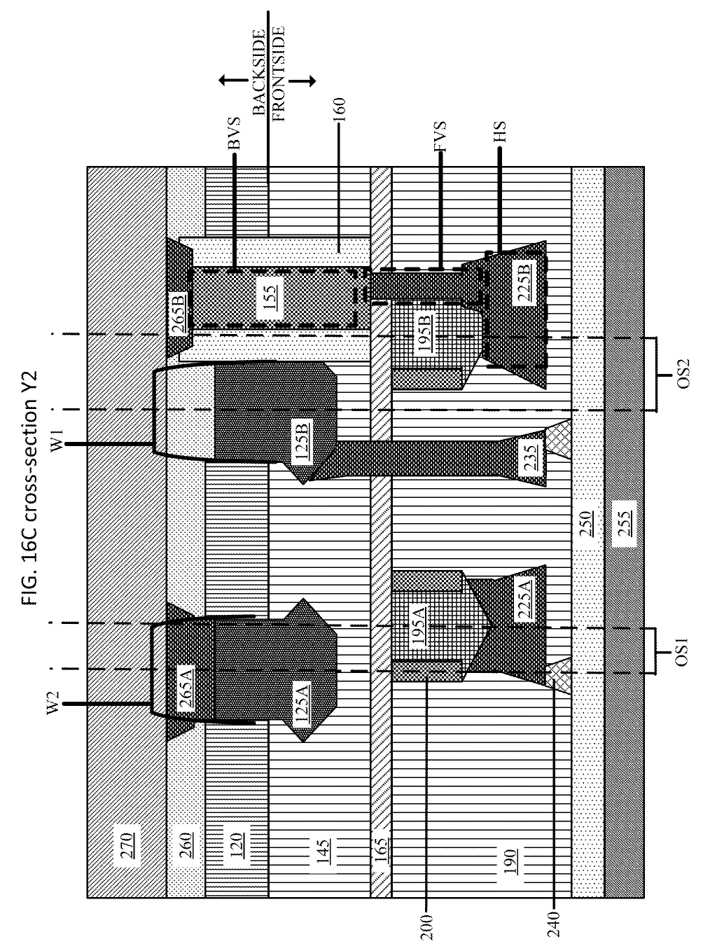

Backside processing of the microelectronic structure is completed in FIGS. 16A-C. FIGS. 16A, 16B, and 16C illustrate cross-sectional views X, Y1, and Y2 show the final device structure following backside contact 265 formation and backside interconnect 270 formation. FIGS. 16A-16C illustrate the formation of the lower nanosheet transistor of the stacked FET, which is the closest device to the backside region. The lower transistor is also known as the bottom or lower section of stacked FET when the lower nanosheet transistor and upper nanosheet transistor utilize a shared gate, via the gate connection openings 167. Therefore, the lower nanosheet transistor or lower section of the stacked FET will also be referred to as the backside section of the stacked nanosheet transistor.

The backside contact 265 formation may involve any of the etching/removal processes previously described to form trenches within the BILD 260. A lithography layer and/or sacrificial protection layer (not shown) is formed on the backside surface of the BILD 260. The lithography layer and the BILD 260 are etched to form a backside contact trench (not shown) within the BILD 260 above the backside surface of the first lower source/drain 125A (e.g., first backside source/drain 125A, first PFET source/drain 125A). The lithography layer, the BILD 260, and the via dielectric liner 160 re etched to form a backside contact trench (not shown) to the backside surface of the via 155. The backside contact 265A is formed by filling the trench above the backside surface of the first lower source/drain 125A (e.g., first backside source/drain 125A, first PFET source/drain 125A) with a conductive metal. The backside contact 265B is formed by filling the trench above the backside surface of the via 155 with a conductive metal.

The backside interconnect 270 is formed on the backside surfaces of the backside contacts 265A, 265B, and the backside surface of the BILD 260. The backside interconnect 270 enabling electrical connectivity in the lower/backside portion of the microelectronic structure through the backside contact 265A located on the backside surface of the first lower source/drain 125A (e.g., first backside source/drain 125A, first PFET source/drain 125A). The backside interconnect 270 further enabling electrical connectivity between the upper/frontside and lower/backside portions of the microelectronic structure through the backside contact 265B and the via 155.

FIG. 16A illustrates a cross-section X of the microelectronic structure after backside contact 265A and backside interconnect 270 formation. The final microelectronic device structure from the cross-section X perspective includes the backside interconnect 270 formed on the backside surface of the backside contact 265A and the backside surface of the BILD 260. The backside contact 265A spanning an entire width of the backside surface of the first lower source/drain 125A (e.g., first backside source/drain 125A, first PFET source/drain 125A). The first lower source/drain 125A (e.g., first backside source/drain 125A, first PFET source/drain 125A) and the second lower source/drain 125B (e.g., second backside source/drain 125B, second PFET source/drain 125B) extending beyond the backside surfaces of the lower gate 130 and lower inner spacers 135 to a depth D1 within the BILD 260. The lower/bottom/backside transistor of the stacked FET further including lower channel layers 140 and bottom/lower dielectric isolation layer 145. The lower/bottom/backside transistor of the stacked FET being separated from the upper/top/frontside transistor of the stacked FET and frontside region of the stacked FET by the middle dielectric isolation layer 165.

The frontside region of the stacked FET being located to the frontside of the middle dielectric isolation layer. The upper/top/frontside transistor including the first upper source/drain 195A (e.g., first frontside source/drain 195A, first NFET source/drain 195A), the second upper source/drain 195B (e.g., second frontside source/drain 195B, second NFET source/drain 195B), upper gate 205, upper channel layers 170, upper inner spacers 180, upper dielectric isolation layer 190 and SAC cap 210.

The upper source/drain contact 225B extending through the SAC cap 210 beyond a frontside surface of the upper gate 205 and upper inner spacers 180 to a depth D2. The upper source/drain contact 225B being formed as a result of the selective dielectric RIE described in detail in FIGS. 9A-c, the selective dielectric RIE being selective to the SAC cap 210 without damaging the upper inner spacers 180. The upper source/drain contact 225B contacting the frontside surface of the second upper source/drain 195B (e.g., second frontside source/drain 195B, second NFET source/drain 195B). The frontside surface of the upper source/drain contact 225B being covered by the upper dielectric isolation layer 190.

The upper source/drain contact 225A extending through the upper dielectric isolation layer 190 to a depth D3 as a result of the additional patterning described in detail in FIGS. 11A-C. The depth D3 of the upper source/drain contact 225A being less than the depth D2 of the upper source/drain contact 225B. The frontside surface of the upper source/drain contact 225A being partially covered by upper dielectric isolation layer 190 with the remaining portion in contact with one of the plurality of metal line(s) 240 or metal track(s) 240. The plurality metal line(s) 240 or metal track(s) 240 being formed as a result of the etching of the upper dielectric isolation layer 190 described in detail in FIGS. 12A-C. The frontside surfaces of the plurality of metal line(s) 240 or metal track(s) 240 and upper dielectric isolation layer 190 being covered by the BEOL layer 250. The frontside surface of the BEOL layer 250 being covered by the carrier wafer 255, the carrier wafer 255 being used to flip the microelectronic structure over following the final stages of frontside processing in FIGS. 12A-C for backside processing starting at FIGS. 13A-C.

FIG. 16B illustrates a cross-section Y1 of the microelectronic structure after backside contact 265 (not shown in the cross-section Y1 perspective) and backside interconnect 270 formation. The final microelectronic device structure from the cross-section Y1 perspective includes the backside interconnect 270 formed over the backside surface of the BILD 260. The BILD 260 covering the backside surfaces of the STI layer 120 and portions of the backside surfaces of the lower gate 130 located above the backside of the lower channel layers 140. The BILD 260 additionally covering side portions of the STI layer 120 where the BILD 260 reaches the backside surface of the lower gate 130.

FIG. 16B further illustrates the lower gate cut(s) 150 which define the individual gate regions for the bottom/lower/backside transistors of the stacked FET and the upper gate cut(s) 151 which define the individual gate regions of the upper/top/frontside transistors of the stacked FET. Separating the bottom/lower/backside transistors and the upper/top/frontside transistors of the stacked FET is the middle dielectric isolation layer 165. The middle dielectric isolation layer 165 including gate connection openings 167, which are described in detail at FIGS. 5, facilitate electrical connectivity between the NFET active regions of the upper/top/frontside transistor and the PFET active region of the lower/bottom/backside transistor.

The cross-section Y1 perspective of FIG. 15B additionally shows the upper channel layers 170 and the upper gate 205 of the upper/top/frontside transistor of the stacked FET. The frontside surfaces of the upper gate 205 and the upper gate cut(s) 151 being covered by SAC cap 210. The SAC cap 210 including the upper gate contacts 230 resulting from the etching and metallization processes described in FIGS. 11A-C. Each of the upper gate contacts 230 being in contact with one of the plurality of metal line(s) 240 or metal track(s) 240 formed by etching the upper dielectric isolation layer 190 described in detail in FIGS. 12A-C. The frontside surfaces of the plurality of metal line(s) 240 or metal track(s) 240 and upper dielectric isolation layer 190 being covered by the BEOL layer 250. The frontside surface of the BEOL layer 250 being covered by the carrier wafer 255, the carrier wafer 255 being used to flip the microelectronic structure over following the final stages of frontside processing in FIGS. 12A-C for backside processing starting at FIGS. 13A-C.

FIG. 16C illustrates a cross-section Y2 of the microelectronic structure after backside contact 265A, backside contact 265B, and backside interconnect 270 formation. The final microelectronic device structure from the cross-section Y2 perspective includes the backside interconnect 270 formed on the backside surfaces of backside contact 265A, backside contact 265B, and BILD 260. The first stacked FET is shown being located adjacent to the second stacked FET of the stacked FET array.

The backside interconnect 270 enabling electrical connectivity in the lower/backside portion of the microelectronic structure through the backside contact 265A located on the backside surface of the first lower source/drain 125A (e.g., first backside source/drain 125A, first PFET source/drain 125A). The backside contact 265A extending the length of the BILD 260 past a backside surface of the STI layer 120 contacting the backside surface of the first lower source/drain 125A (e.g., first backside source/drain 125A, first PFET source/drain 125A).

The backside interconnect 270 further enabling electrical connectivity between the upper/top/frontside and lower/bottom/backside portions of the microelectronic structure through the backside contact 265B and the via 155, as shown by the backside via section BVS, frontside via section FVS and the horizontal section HS of the frontside contact 225B (e.g., first frontside contact). The backside contact 265B extending a portion of the BILD 260 depth, through the backside surface of the dielectric liner 160, and contacting the entire backside surface of the via 155. The via 155 connecting the backside contact 265B and the upper source/drain contact 225B, the upper source/drain contact 225B (e.g., first frontside contact) extending from the frontside of the microelectronic structure to the backside of the microelectronic structure through the middle dielectric isolation layer 165. The upper source/drain contact 225B (e.g., first frontside contact) including the horizontal section HS and the frontside via section FVS, shown in FIG. 16C. The horizontal section HS being in contact with the frontside surface of the second upper source/drain 195B (e.g., second frontside source/drain 195B, second NFET source/drain 195B). The frontside via section FVS being in contact with a first vertical side of the second upper source/drain 195B (e.g., second frontside source/drain 195B, second NFET source/drain 195B). The frontside via section FVS extending towards a backside region of the stacked FET to the backside via section BVS, the backside via section BVS being in direct contact with the backside contact 265B. Lower source/drain contact 235 also extending from the frontside of the microelectronic structure to the backside of the microelectronic structure through the middle dielectric isolation layer 165 contacting the second lower source/drain 125B (e.g., second backside source/drain 125B, second PFET source/drain 125B).

The offset orientation of the stacked FET is further illustrated in FIG. 16C using dashed brackets OS1 and OS2. OS1 representing the offset of the first lower source/drain 125A (e.g., first backside source/drain 125A, first PFET source/drain 125A) and the first upper source/drain 195A (e.g., first frontside source/drain 195A, first NFET source/drain 195A). OS1 showing an approximate length of the offset using an approximate center of the first lower source/drain 125A (e.g., first backside source/drain 125A, first PFET source/drain 125A) and the approximate center of the first upper source/drain 195A (e.g., first frontside source/drain 195A, first NFET source/drain 195A). OS2 representing the offset of the second lower source/drain 125B (e.g., second backside source/drain 125B, second PFET source/drain 125B) and the second upper source/drain 195B (e.g., second frontside source/drain 195B, second NFET source/drain 195B). OS2 showing an approximate length of the offset using an approximate center of the second lower source/drain 125B (e.g., second backside source/drain 125B, second PFET source/drain 125B) and the approximate center of the second upper source/drain 195B (e.g., second frontside source/drain 195B, second NFET source/drain 195B). The offsets OS1 and OS2 may be the same, similar, or a different length value depending on variations in the fabrication process. The offsets represented by OS1 and OS2 are not meant to be seen as limiting and may vary in other embodiments of the present invention.

In FIG. 16C the width W2 of the first lower source/drain 125A (e.g., first backside source/drain 125A, first PFET source/drain 125A) and the width W1 the second lower source/drain 125B (e.g., second backside source/drain 125B, second PFET source/drain 125B) are shown. The Width W2 of the first lower source/drain 125A (e.g., first backside source/drain 125A, first PFET source/drain 125A) and the width W1 of the second lower source/drain 125B (e.g., second backside source/drain 125B, second PFET source/drain 125B) are different, measured along the Y-axis parallel to the gate direction.

FIG. 16C further illustrates the upper source/drain spacers 200 extending vertically along both sides of the first upper source/drain 195A (e.g., first frontside source/drain 195A, first NFET source/drain 195A) and vertically along one side of the second upper source/drain 195B (e.g., second frontside source/drain 195B, second NFET source/drain 195B) the other side of the second upper source/drain 195B being filled with the conductive metal of the upper source/drain contact 225B formed as a result of the removal of the upper/source drain spacer 200 on that side as described in FIGS. 10A-C. The second upper source/drain 195B (e.g., second frontside source/drain 195B, second NFET source/drain 195B) being sandwiched between a first spacer of the upper source/drain spacers 200 and the frontside via section FVS of the upper source/drain contact 225B (e.g., frontside contact). This increases the surface area contact between the upper source/drain contact 225B (e.g., frontside contact) and the second upper source/drain 195B (e.g., second frontside source/drain 195B, second NFET source/drain 195B).

Upper source/drain contact 225A contacting the entire frontside surface of the first upper source/drain 195A (e.g., first frontside source/drain 195A, first NFET source/drain 195A) and lower source/drain contact 235 being in contact with a portion of the frontside surface of the second lower source/drain 125B (e.g., second backside source/drain 125B, second PFET source/drain 125B). Both the upper source/drain contact 225A and the lower source/drain contact 235 being in contact with one of the plurality of metal line(s) 240 or metal track(s) 240 with their remaining frontside surfaces being covered by upper dielectric isolation layer 190. The frontside surfaces of the upper dielectric isolation layer 190 and the frontside surfaces of the metal line(s) 240 or metal track(s) 240 being covered by the BEOL layer 250. The frontside surface of the BEOL layer 250 being covered by the carrier wafer 255, the carrier wafer 255 being used to flip the microelectronic structure over following the final stages of frontside processing at FIGS. 12A-C for backside processing starting at FIGS. 13A-C.

While the invention has been shown and described with reference to certain exemplary embodiments thereof, it will be understood by those skilled in the art that various changes in form and details may be made therein without departing from the spirit and scope of the present invention as defined by the appended claims and their equivalents. For example, the first stacked FET, the second stacked FET, may be referred to interchangeably. The first frontside source/drain and the second frontside source/drain, may be referred to interchangeably. The first backside source/drain and and second backside source/drain may be referred interchangeably. This does not depart from the spirit and scope of the present invention.

A microelectronic structure that includes stacked FET including a frontside section of the stacked FET and a backside section of stacked FET. An active region of the frontside section of the stacked FET and an active region of the backside section of stacked FET are offset from each other. A frontside contact 225B that includes a horizontal section HS and a frontside via section FVS. The horizontal section HS is in contact with a frontside surface of a frontside source/drain 195B and the frontside via section FVS is in direct contact with a vertical side surface of the frontside source/drain 195B. The frontside via section FVS extends towards the backside region of the stacked FET.

The frontside source/drain 195B is sandwiched between a spacer 200 and the frontside via section FVS of the frontside contact 225B.

The microelectronic structure further including a backside source/drain 125B, a backside via section BVS, and a dielectric liner 160, the dielectric liner 160 located between the backside source/drain 125B and the backside via section BVS. The dielectric liner 160 being in direct contact with the backside source/drain 125B and also in direct contact with the backside via section BVS. The dielectric liner 160 separating a conductive metal of the backside via section BVS and the backside source/drain 125B.

The microelectronic structure further including a backside contact 265B, the backside via section BVS, the backside surface of the backside contact 265B being in direct contact with the backside via section BVS.

A microelectronic structure that includes a stack FET array. The stacked FET array includes at least a first stacked FET and a second stacked FET. The first stack FET is located adjacent to the second stack FET. The first stacked FET includes a first frontside section and a first backside section. A first frontside contact 225B that includes a horizontal section HS and a frontside via section FVS. The horizontal section HS is in contact with a frontside surface of a first frontside source/drain 195B and the frontside via section FVS is in direct contact with a first vertical side surface of the first frontside source/drain 195B. The frontside via section FVS extending towards a backside region of the first stacked FET.

The microelectronic structure further including a first spacer 200; a second spacer 200, and a third spacer 200. The first spacer 200 is located along a second vertical side surface of the first frontside source/drain 195B. The second spacer 200 is located along a first vertical side of a second frontside source/drain 195A. The third spacer 200 is located along a second vertical side of the second frontside source/drain 195A.

The first frontside source/drain 195A is located between the frontside via section FVS and the first spacer 200. The first vertical side surface of the first frontside source/drain 195A and the second vertical side surface of the first frontside source/drain 195A are different vertical sides.

The second frontside source/drain 195B is located between the second spacer 200 and the third spacer 200. The first vertical side surface of the second frontside source/drain 195B and the second vertical side surface of the second frontside source/drain 195B are different vertical sides.

The first stacked FET includes a first backside source/drain 125B. The second stacked FET includes a second backside source/drain 125A. A width W1 of the first backside source/drain 125B and a width W2 of the second backside source/drain 125A, as measured along a Y-axis parallel to a gate direction, are different.

The microelectronic structure further including a first backside source/drain 125B, a backside via section BVS and a dielectric liner 160. The dielectric liner 160 located between the first backside source/drain 125B and the backside via section BVS. The dielectric liner 160 being in direct contact with both the first backside source/drain 125B and the backside via section BVS. The dielectric liner 160 separating a conductive metal of the backside via section BVS and the first backside source/drain 125B.

The first frontside source/drain 195B of the first stacked FET and a second frontside source/drain 195A of the second stacked FET are both NFET. The first backside source/drain 125B of the first stacked FET and a second backside source/drain 125A of the second stacked FET are both PFET. The backside surface of the first backside source/drain 125B and the second backside source/drain 125A are at a first level, and a backside surface of the lower gate 130 of the backside transistor is at a second level. The first level and the second level being different.

The microelectronic structure further including a first backside contact 265B, the backside surface of the first backside contact 265B being in direct contact with a backside via section BVS.

A method comprising forming a stack FET array. Forming the stacked FET array including at least a first stacked FET and a second stacked FET. The first stack FET being located adjacent to the second stack FET. The first stacked FET includes a first frontside section and a first backside section. Forming a first frontside contact 225B that includes a horizontal section HS and a frontside via section FVS. The horizontal section HS being in contact with a frontside surface of a first frontside source/drain 195B and the frontside via section FVS being in direct contact with a first vertical side surface of the first frontside source/drain 195N. The frontside via section FVS extends towards a backside region of the first stacked FET.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stacked FET including a frontside section of the stacked FET and a backside section of stacked FET, wherein an active region of the frontside section of the stacked FET and an active region of the backside section of stacked FET are offset from each other; and
a frontside contact that includes a horizontal section and a frontside via section, wherein the horizontal section is in contact with a frontside surface of a frontside source/drain and the frontside via section is in direct contact with a vertical side surface of the frontside source/drain, wherein the frontside via section extends towards the backside region of the stacked FET.

2. The microelectronic structure of claim 1, wherein the frontside source/drain is sandwiched between a spacer and the frontside via section of the frontside contact.

3. The microelectronic structure of claim 1, further comprising:
a backside via section; and
a dielectric liner, wherein the backside section of the stacked FET includes a backside source/drain, wherein the dielectric liner is located between the backside source/drain and the backside via section.

4. The microelectronic structure of claim 3, wherein the dielectric liner is in direct contact with the backside source/drain.

5. The microelectronic structure of claim 3, wherein the dielectric liner is in direct contact with the backside via section.

6. The microelectronic structure of claim 3, wherein the dielectric liner separates a conductive metal of the backside via section and the backside source/drain.

7. The microelectronic structure of claim 1, further comprising:
a backside contact; and
a backside via section, wherein a backside surface of the backside contact is in direct contact with the backside via section.

8. A microelectronic structure comprising:
a stack FET array, wherein the stacked FET array includes at least a first stacked FET and a second stacked FET, wherein the first stack FET is located adjacent to the second stack FET, wherein the first stacked FET includes a first frontside section and a first backside section; and
a first frontside contact that includes a horizontal section and a frontside via section, wherein the horizontal section is in contact with a frontside surface of a first frontside source/drain and the frontside via section is in direct contact with a first vertical side surface of the first frontside source/drain, wherein the frontside via section extends towards a backside region of the first stacked FET.

9. The microelectronic structure of claim 8, further comprises:
a first spacer;
a second spacer; and
a third spacer, wherein the first spacer is located along a second vertical side surface of the first frontside source/drain, wherein the second spacer is located along a first vertical side of a second frontside source/drain, and wherein the third spacer is located along a second vertical side of the second frontside source/drain.

10. The microelectronic structure of claim 9, wherein the first frontside source/drain is located between the frontside via section and the first spacer.

11. The microelectronic structure of claim 9, wherein the first vertical side surface of the first frontside source/drain and the second vertical side surface of the first frontside source/drain are different vertical sides.

12. The microelectronic structure of claim 9, wherein the second frontside source/drain is located between the second spacer and the third spacer.

13. The microelectronic structure of claim 9, wherein the first vertical side surface of the second frontside source/drain and the second vertical side surface of the second frontside source/drain are different vertical sides.

14. The microelectronic structure of claim 8, wherein the first stacked FET includes a first backside source/drain, wherein the second stacked FET includes a second backside source/drain, and wherein a width of the first backside source/drain and a width of the second backside source/drain, as measured along a Y-axis parallel to a gate direction, are different.

15. The microelectronic structure of claim 8, further comprising:
a backside via section; and
a dielectric liner, wherein the backside section of the first stacked FET includes a first backside source/drain, wherein the dielectric liner is located between the first backside source/drain and the backside via section, wherein the dielectric liner is in direct contact with both the first backside source/drain and the backside via section, and wherein the dielectric liner separates a conductive metal of the backside via section and the first backside source/drain.

16. The microelectronic structure of claim 8, wherein the first frontside source/drain of the first stacked FET and a second frontside source/drain of the second stacked FET are both NFET, and wherein a first backside source/drain of the first stacked FET and a second backside source/drain of the second stacked FET are both PFET.

17. The microelectronic structure of claim 16, wherein a backside surface of the first backside source/drain and the second backside source/drain are at a first level, and wherein a backside surface of a gate of the first backside section is at a second level.

18. The microelectronic structure of claim 17, wherein the first level and the second level are different.

19. The microelectronic structure of claim 8, further comprising:
a first backside contact, wherein a backside surface of the first backside contact is in direct contact with a backside via section.

20. A method comprising:
forming a stack FET array, wherein the stacked FET array includes at least a first stacked FET and a second stacked FET, wherein the first stack FET is located adjacent to the second stack FET, wherein the first stacked FET includes a first frontside section and a first backside section; and
forming a first frontside contact that includes a horizontal section and a frontside via section, wherein the horizontal section is in contact with a frontside surface of a first frontside source/drain and the frontside via section is in direct contact with a first vertical side surface of the first frontside source/drain, wherein the frontside via section extends towards a backside region of the first stacked FET.
